(19) United States
(12) Patent Application Publication
(10) Pub. No.: US 2026/0253643 A1
(43) Pub. Date: Aug. 27, 2026

(54) NON-VOLATILE MEMORY ERASE SCHEME

(71) Applicant: Micron Technology, Inc., Boise, ID (US)

(72) Inventor: Jun Xu, San Jose, CA (US)

(73) Assignee: Micron Technology, Inc., Boise, ID (US)

(21) Appl. No.: 19/061,894

(22) Filed: Feb. 24, 2025

Related U.S. Application Data
(60) Provisional application No. 63/564,952, filed on Mar. 13, 2024.

(51) Int. Cl. G11C 16/16; G06F 3/06; G11C 16/04

(52) U.S. Cl. CPC G11C 16/16; G06F 3/0611; G06F 3/0659; G06F 3/0679; G11C 16/0483

(57) ABSTRACT

Methods, systems, and devices for techniques for erasing data in a memory device are provided. The memory device comprises a plurality of memory blocks. Each of the plurality of memory blocks comprises a plurality of word line segments. Each of the plurality of word line segments comprises one or more word lines forming a subset of word lines in the memory block. The memory device further comprises a memory controller configured to perform receiving an erase command for erasing data in the memory block, and in response to receiving the erase command, causing to apply one or more erase pulses to the plurality of word line segments to ramp up word lines of different word line segments of the memory block in different time periods such that while data erasing begins at a first word line segment, data erasing does not begin at another word line segment.

### CROSS-REFERENCE TO RELATED APPLICATION

This application claims priority to U.S. Provisional Application No. 63/564,952, filed on Mar. 13, 2024, entitled “NON-VOLATILE MEMORY ERASE SCHEME,” the content of which is incorporated by reference in its entirety for all purposes.

### TECHNICAL FIELD

This disclosure relates to one or more systems for memory, including techniques for erasing data in a memory device.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells. Information can also be erased from the memory cells and new information can be stored in the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIGS. 1A and 1B illustrate an example of a host system and a memory system that support techniques for erasing data in a memory device in accordance with examples as disclosed herein.

FIG. 1C is a block diagram of a memory device in communication with a memory system controller of a memory system, in accordance with examples as disclosed herein.

FIGS. 2A-2C are illustrative schematics of portions of an array of memory cells in a memory device, in accordance with examples as disclosed herein.

FIG. 2D illustrates an example of a memory device including multiple blocks of memory cells in accordance with examples as disclosed herein.

FIG. 3 is a block diagram of an example apparatus for implementing one or more systems and for performing one or more methods described herein, in accordance with examples as disclosed herein.

FIG. 4 is a diagram illustrating an example of voltage waveforms of an erase pulse for word lines and one or more memory lines in a traditional manner.

FIG. 5 is a diagram illustrating an example of voltage waveforms for reducing latency in an erase operation in a memory device according to some embodiments.

FIG. 6 is a diagram illustrating another example of voltage waveforms for reducing latency in an erase operation in a memory device according to some embodiments.

FIG. 7 illustrates a flowchart showing an example method for reducing latency in an erase operation in a memory device according to some embodiments.

FIGS. 8 and 9 illustrate flowcharts showing an example method for ramping up word lines of different word line segments in different time periods according to some embodiments.

FIG. 10 illustrates a flowchart showing another example method for ramping up word lines of different word line segments in different time periods according to some embodiments.

FIG. 11 is a diagram illustrating an example of a memory block comprising one or more word line groups according to some embodiments.

FIGS. 12A-12C are diagrams illustrating an example method for reducing a maximum erase voltage in an erase operation in a memory device according to some embodiments.

FIG. 13 is a diagram illustrating an example of voltage waveforms for performing an erase operation for a plurality of word line segments in different time periods according to some embodiments.

FIG. 14 illustrates a flowchart showing an example method for reducing a maximum erase voltage in an erase operation in a memory device according to some embodiments.

FIG. 15 illustrates a flowchart showing an example method for preparing for electrical isolation of a memory pillar portion according to some embodiments.

FIG. 16 illustrates a flowchart showing an example method for electrically isolating a memory pillar portion according to some embodiments.

FIG. 17 illustrates a flowchart showing an example method for boosting a voltage of the isolated memory pillar portion according to some embodiments.

FIG. 18 illustrates a flowchart showing an example method for performing an erase operation of the target word line group using word line segmentation according to some embodiments.

### DETAILED DESCRIPTION

Erase operation is one of the commonly performed operations for a memory device. Typically, an erase operation is performed to a memory block, which is the smallest unit for an erase operation. A memory block may include multiple word line segments. Each of the word line segments may include one or more word lines. Conventionally, to erase a memory block, an erase pulse is applied such that the voltage of all word lines in the memory blocks stay at a low voltage while the memory lines associated with the memory block are ramped up to an erase voltage (Vₑᵣₐ). The erase voltage is then kept flat for the erase operation to occur and then ramp down during a recovery phase of the erase operation. In an erase pulse used in an erase operation, a ramping up period may be a sufficiently long period. Before the ramping up period is completed, substantial erase operation may not occur. Therefore, this may cause a significant erase latency when performing erase operations block by block. The ramping rate during an erase operation is limited by gate-induced drain leakage (GIDL) capability and loading. GIDL generally refers to the leakage current that flows from the drain to the source of a transistor (e.g., a MOSFET) when the transistor is in the off state, induced by the gate voltage. Each of the plurality of memory blocks may comprise a high number of word lines (e.g., a few hundred word lines), so the loading is considerable large. As a result, the erase operation may have a significant delay.

Long latency in an erase operation is generally not desirable. An erase operation may be suspended when, for example, a memory controller issues a suspend command. When a suspend command is received, the erase operation cannot be completed and erase pulse ramps down to recover. Typically, the erase pulse has a required minimum flattop time period such that it does not ramp down immediately after the suspend command is received. After the erase pulse ramps down, and other operations (e.g., read, write) are performed, the erase pulse needs to ramp up again to resume the erase operation that was interrupted. The ramping up of the erase pulse again causes significant delays. Furthermore, if the latency of the overall erase operation is long, it increases the chances that another suspend command may be received during the erase operation, and therefore increases the chances of the erase operation being interrupted again. Thus, long latency of an erase operation reduces the overall efficiency of the memory device operation.

In accordance with various examples described in the present disclosure, by using a method of word line segmentation, a memory controller causes to apply one or more erase pulses to a plurality of word line segments to ramp up word lines of different word line segments of the memory block in different time periods. As a result, the high number of word lines can be partitioned into the plurality of word line segments. This reduces the loading for the driver of the word lines to ramp up the voltages of the word lines. Therefore, a time for the ramping up period may be reduced, thereby reducing latency in the erase operation and improving quality of service (QoS).

As described above, GIDL may occur in a memory device or any semiconductor devices. Memory devices or other semiconductor devices may be three-dimensional (3D) devices that have an increasing number of layers or tiers. A 3D device can have a higher capacity than a 2D device. In a typical 3D memory device, for example, multiple layers are stacked together with one or more memory pillars disposed vertically in the middle. The memory pillars may act as the channel region of the memory device. The multiple layers or tiers of the memory device may form groups or decks. A deck of the memory device may be processed together (e.g., patterned together) when forming the memory pillar associated thereof. A layer or tier of the memory device may have one or more word lines or word line groups. Each deck may have one or more word line segments. A word line segment may have fewer or more word lines than those in a deck. For example, a deck may have two word line segments distributed in one or more layers. In some cases, an erase operation can be performed to a word line group (e.g., a deck), and not to the entire memory block. By not applying the erase operation to the entire memory block, the erase operation can be performed faster.

In an erase operation of a memory device, GIDL may introduce many electronic holes (or simply holes) with positive charges, which can enter memory pillars of a memory block. An erase operation is affected by the GIDL effect, which causes the electronic holes to enter the memory pillar. For a 3D memory device having many layers forming multiple word line groups or decks, some portions of the memory pillar (e.g., an interface portion between word line groups or decks and located far away from bit lines or common source (SRC) lines) may have a weaker GIDL effect than other groups or decks. This may be caused by the processing of the device, because doping level of certain portions of the memory pillar may vary due to process variations. In those portions of the memory pillar, the GIDL effect may be weak. During an erase operation, the bit lines or the SRC lines are applied a high erase voltage (e.g., Vₑᵣₐ=20V) and the portion memory pillar that is close to the bit lines or the SRC lines may have the same high voltage (e.g., 20V) as well, while other portions that are further away from the bit lines or the SRC lines may have a lower voltage (e.g., 18V) because of the weaker GIDL effect. When a memory pillar portion has a voltage that is lower than an erase voltage (Vₑᵣₐ), there may not be a sufficiently voltage difference to perform the erase operation. To perform the erase operation, the bit line voltages would need to be increased, but doing so may cause reliability issues.

In this disclosure, a memory controller prepares for electrical isolation of a memory pillar portion associated with a target word line group, electrically isolates the memory pillar portion associated with the target word line group, and boosts a voltage of the isolated memory pillar portion. Therefore, there is no need to increase the bit line voltage to be more than the erase voltage to compensate for the loss of voltage in the particular memory pillar portion due to the weaker GIDL effect. The target word line group can then perform an erase operation using a voltage that is the same as, or less than, the erase voltage. The disclosed methods and structures therefore mitigate or eliminate the impact of the weaker GIDL effect, reduce the error of the erase operation, and enhance the reliability of the memory device.

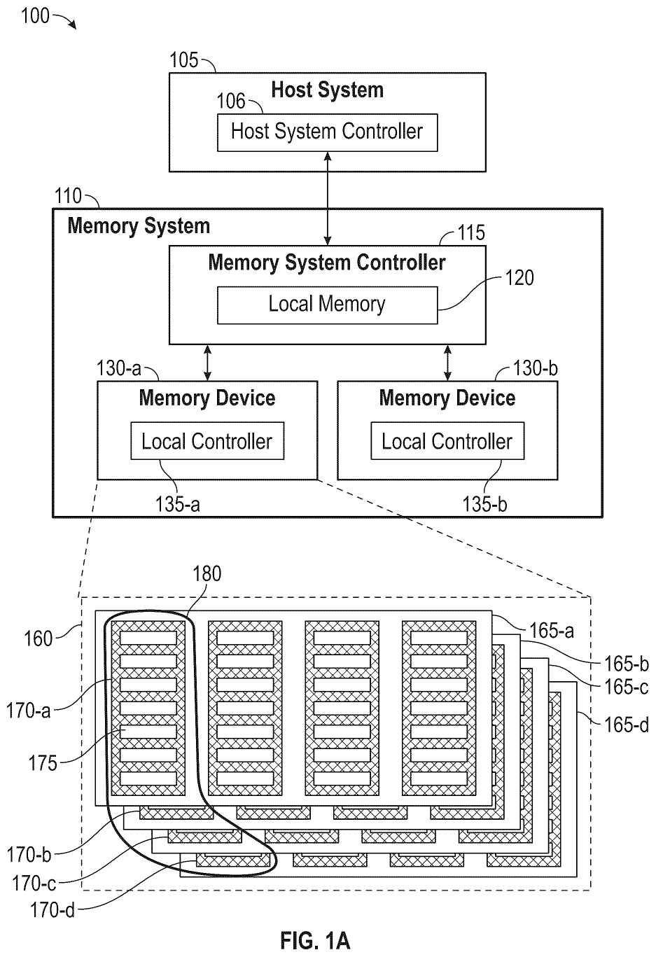

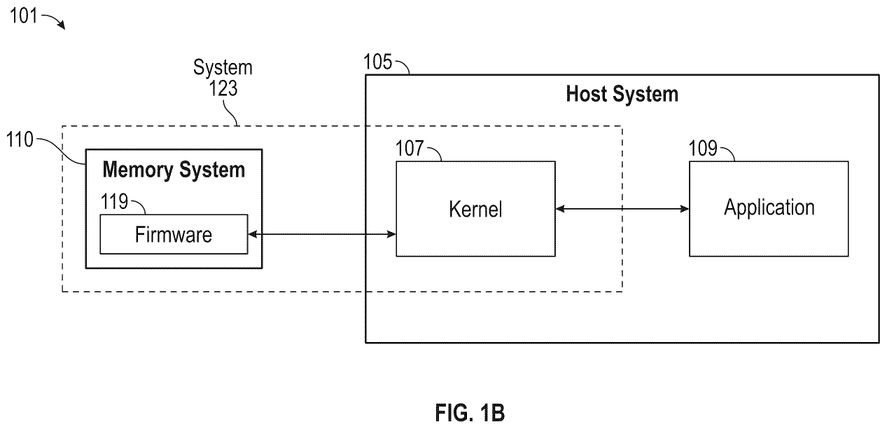

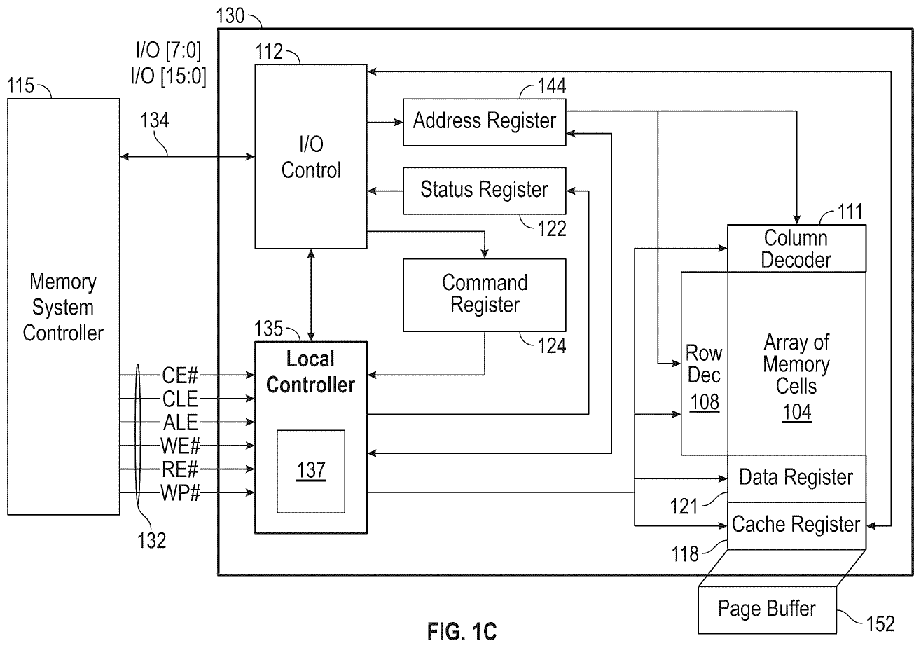

FIG. 1A illustrates an example of a system 100 that supports techniques for erasing data in a memory device in accordance with examples as disclosed herein. System 100 includes a host system 105 coupled with a memory system 110. System 100 may be included in a computing device such as a desktop computer, a laptop computer, a network server, a mobile device, a vehicle (e.g., airplane, drone, train, automobile, or other conveyance), an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

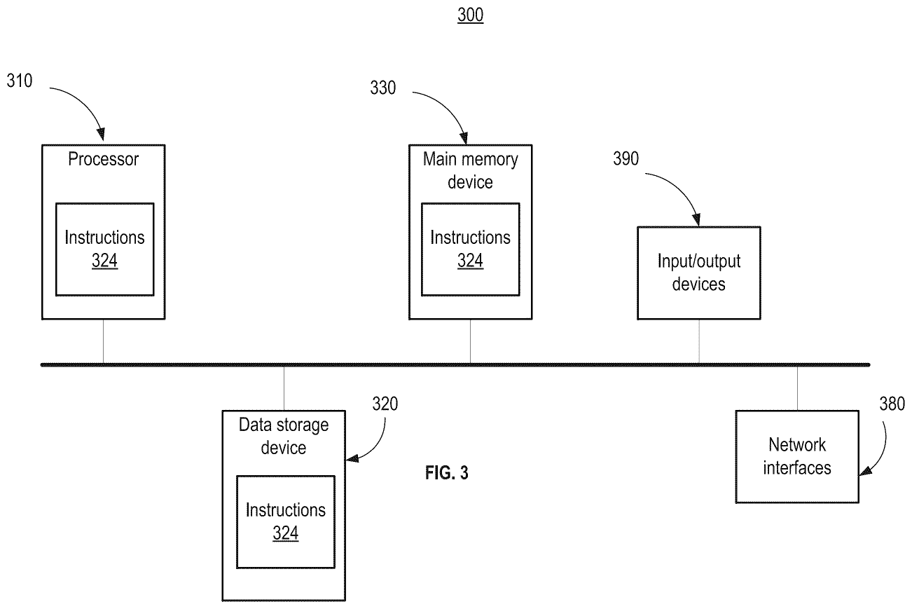

System 100 may include a host system 105, which may be coupled with memory system 110. In some examples, this coupling may include an interface with a host system controller 106, which may be an example of a controller or control component configured to cause host system 105 to perform various operations in accordance with examples as described herein. Host system 105 may include one or more devices and, in some cases, may include a processor chipset and a software stack executed by the processor chipset. Host system 105 may be implemented by, for example, an apparatus 300 shown in FIG. 3. For example, host system 105 may include an application configured for communicating with memory system 110 or a device therein. The processor chipset may include one or more cores, one or more caches (e.g., memory local to or included in host system 105), a memory controller (e.g., NVDIMM controller), and a storage protocol controller (e.g., peripheral component interconnect express (PCIe) controller, serial advanced technology attachment (SATA) controller). Host system 105 may use memory system 110, for example, to write data to memory system 110 and read data from memory system 110. Although one memory system 110 is shown in FIG. 1A, the host system 105 may be coupled with any quantity of memory systems 110.

Host system 105 may be coupled with memory system 110 via at least one physical host interface. Host system 105 and memory system 110 may, in some cases, be configured to communicate via a physical host interface using an associated protocol (e.g., to exchange or otherwise communicate control, address, data, and other signals between memory system 110 and host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a Graphical Double Data Rate (GDDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of host system 105 and a memory system controller 115 of memory system 110. In some examples, host system 105 may be coupled with memory system 110 (e.g., host system controller 106 may be coupled with memory system controller 115) via a respective physical host interface for each memory device 130 included in the memory system 110, or via a respective physical host interface for each type of memory device 130 included in memory system 110.

Memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1A, memory system 110 may include any quantity of memory devices 130. Further, if the memory system 110 includes more than one memory device 130, different memory devices 130 within the memory system 110 may include the same or different types of memory cells.

Memory system controller 115 may be coupled with and communicate with host system 105 (e.g., via the physical host interface) and may be an example of a controller or control component configured to cause memory system 110 to perform various operations in accordance with examples as described herein. Memory system controller 115 may also be coupled with and communicate with memory devices 130 to perform operations such as reading data, writing data, erasing data, or refreshing data at a memory device 130—among other such operations—which may generically be referred to as access operations. In some cases, memory system controller 115 may receive commands from the host system 105 and communicate with one or more memory devices 130 to execute such commands (e.g., at memory arrays within the one or more memory devices 130). For example, memory system controller 115 may receive commands or operations from host system 105 and may convert the commands or operations into instructions or appropriate commands to achieve the desired access of memory devices 130. In some cases, memory system controller 115 may exchange data with host system 105 and with one or more memory devices 130 (e.g., in response to or otherwise in association with commands from host system 105). For example, memory system controller 115 may convert responses (e.g., data packets or other signals) associated with the memory devices 130 into corresponding signals for the host system 105.

Memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from host system 105 and physical addresses (e.g., physical block addresses) associated with memory cells within memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to memory system controller 115. Memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

Memory system controller 115 may also include a local memory 120. In some cases, local memory 120 may include read-only memory (ROM) or other memory that may store operating code (e.g., executable instructions) executable by memory system controller 115 to perform functions ascribed herein to memory system controller 115. In some cases, local memory 120 may additionally, or alternatively, include static random access memory (SRAM) or other memory that may be used by memory system controller 115 for internal storage or calculations, for example, related to the functions ascribed herein to memory system controller 115.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on a same semiconductor die or within a same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1A, a memory device 130-a may include a local controller 135-a and a memory device 130-b may include a local controller 135-b. In the examples illustrated in this disclosure (e.g., the example shown in FIG. 1C), local controller 135 is disposed on the same semiconductor die as the memory array (e.g., array 104); and a separate memory system controller 115 is disposed on a different die. In other examples, some portions of memory device 130 may be disposed on a first die and other portions of memory device 130 may be disposed on a second die different from the first die. For instance, the first die may include the array of memory cells 104 and its associated circuitry such as the column decoder 111 and row decoder 108, etc. The second die may include logic circuitry, power circuitry, or other circuitry of device 130. Thus, the second die may include system controller 115, I/O control 112, etc. In this example, the first die has no local controller, and the second die includes the system controller 115. The first die and the second die can be hybrid bonded together using, for example, through-hole vias (TSVs) such that they are electrically connected. The first die and the second die may also be wafer-bonded using flip-chip bonding technologies, etc. In this disclosure, a memory system controller 115 and a local controller 135 may both be referred to as memory controllers, or a first memory controller and a second memory controller, for simplicity. It is understood that while they may be different controllers, certain operations disclosed herein may be caused or performed by either or both memory controllers, unless otherwise specified.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of memory blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of memory blocks 170 and, in some cases, concurrent operations may be performed on different planes 165. For example, concurrent operations may be performed on memory cells within different blocks 170 so long as the different blocks 170 are in different planes 165. In some cases, an individual memory block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in a same page 175 may share (e.g., be coupled with) a common word line, and memory cells in a same string may share (e.g., be coupled with) a common digit line (which may alternatively be referred to as a bit line). Example memory cells structures are shown in more detail below using illustrative schematics.

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a memory block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, L2P (logical-to-physical) mapping tables may be maintained and data may be marked as valid or invalid at the page level of granularity, and a page 175 may contain valid data, invalid data, or no data. Invalid data may be data that is outdated, which may be due to a more recent or updated version of the data being stored in a different page 175 of the memory device 130. Invalid data may have been previously programmed to the invalid page 175 but may no longer be associated with a valid logical address, such as a logical address referenced by the host system 105. Valid data may be the most recent version of such data being stored on the memory device 130. A page 175 that includes no data may be a page 175 that has never been written to or that has been erased.

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

System 100 may include any quantity of non-transitory computer readable media that support techniques for logical-to-physical table compression. For example, host system 105 (e.g., a host system controller 106), memory system 110 (e.g., a memory system controller 115), or a memory device 130 (e.g., a local controller 135) may include or otherwise may access one or more non-transitory computer readable media storing instructions (e.g., firmware, logic, code) for performing the functions ascribed herein to the host system 105, the memory system 110, or a memory device 130. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

In some cases, a memory system 110 may compress an L2P mapping to expand the quantity of physical addresses mapped by the L2P mapping. For example, if a set of consecutive entries of an uncompressed L2P mapping includes consecutive physical addresses, memory system 110 may compress the consecutive entries into a single entry which includes a starting physical address of the consecutive physical addresses. Additionally, memory system 110 may include an indication of a starting logical address corresponding to the starting physical address in the compressed entry. To identify a physical address within the compressed entry, memory system 110 may determine an offset between a logical address corresponding to the physical address (e.g., a logical address included in a read command for data stored at the physical address) and the starting physical address using the indication, and may apply the offset to the starting physical address to determine the physical address. Compressing the L2P mapping may allow the L2P mapping to cover an expanded range of physical address space without increasing the size of the L2P mapping.

FIG. 1B illustrates an example of a system diagram 101 that illustrates communication between host system 105 and memory system 110 via using a kernel and firmware, in accordance with examples as disclosed herein. System diagram 101 may include a memory system 110, a kernel 107, and an application 109. The memory system 110 may include a firmware 119. Firmware 119 may be implemented by a controller and/or other circuitry of the memory system (e.g., memory system controller 115 and/or local controllers 135 shown in FIG. 1A). In some examples, a system 123 as described herein may include memory system 110 and kernel 107. Additionally, a host system 105 may include kernel 107 and the application 109.

As described above, memory system 110 may include multiple memory devices, including non-volatile memory devices and volatile memory devices (e.g., local memory 120), configured to store and retrieve data. Firmware 119 may refer to software stored within a memory array within memory system 110 (e.g., a non-volatile memory device within the memory system 110) and/or a local memory 120 as shown in FIG. 1A. Firmware 119 may provide low-level control functions for the memory system 110. For example, firmware 119 may function as an interface between the memory system 110 and other components of the system 123, and host system 105 may issue access operations to memory system 110 by interfacing with firmware 119. In some examples, firmware 119 may be or be included within or implemented by a memory system controller 115, as described herein with reference to FIG. 1A. In some examples, memory system 110 may store a logical-to-physical mapping that maps logical addresses to physical addresses within a non-volatile memory device (e.g., in a logical-to-physical table). To perform a memory access operation, memory system 110 may move a portion of the logical-to-physical mapping corresponding to one or more logical addresses (e.g., indicated by kernel 107) from the non-volatile memory device to a volatile memory device.

Kernel 107 may function as an interface between host system 105 and components associated with host system 105, such as an operating system of host system 105. Additionally, kernel 107 may perform resource allocation and file management, among other operations, for host system 105. For example, an application 109 running within host system 105 may access information stored within memory system 110 by issuing commands to kernel 107, which may indicate files to be accessed. Kernel 107 may store mapping information associated with the files. For example, a file may be associated with a file name, and may correspond to a range of logical block addresses. Kernel 107 may store mapping information (e.g., a mapping table) that may track logical block addresses corresponding to files of host system 105. In some examples, application 109 may issue an access command to kernel 107 indicating a file name, and offset, and a length associated with a file to be accessed, and kernel 107 may retrieve a one or more logical block addresses corresponding to the file to be accessed. Kernel 107 may then communicate with firmware 119 to indicate the one or more logical block addresses to memory system 110, and memory system 110 may perform an access operation based on the one or more logical block addresses. Memory system 110 may communicate the accessed information to kernel 107 (e.g., via the firmware 119).

In some examples, kernel 107 may communicate with firmware 119 using information units (e.g., UFS protocol information units (UPIUs)). For example, kernel 107 may issue or receive commands, responses, data, or other information via information units exchanged with the firmware 119. An information unit may refer to a data packet that may contain a header segment and one or more transaction specific fields. In some examples, an information unit may additionally include one or more extended header segments, one or more data segments, or a combination thereof. The header segments of an information unit may indicate information associated with a destination for the information unit, a source of the information unit, a function request, whether additional data or parameters are to be transmitted, whether the additional data or parameters are included within the information unit or to be sent in a following information unit, or any combination thereof. The transaction specific fields may be used for additional fields depending on the operation associated with the information unit. The data segments may be used to include data to be transferred from a device to another.

In some examples, a command information unit (e.g., a command UPIU) may be an example of an information unit associated with the transmission of a command (e.g., an SCSI command) and may indicate a device to perform some operation indicated by the command information unit. For example, the command information unit may include a block descriptor (e.g., a command descriptor block) which may indicate information related to the operation indicated by the command information unit. In some examples, kernel 107 may transfer a command information unit to memory system 110 to indicate memory system 110 of an operation to be performed by memory system 110.

In some examples, to perform an access operation, memory system 110 may load a L2P mapping associated with information to be accessed. For example, memory system 110 may transfer a portion of a logical-to-physical mapping associated with the information to be accessed from a non-volatile memory device of memory system 110 (e.g., NAND memory) to a volatile memory device (e.g., an SRAM) of the memory system 110. In another example, host system 105 may notify memory system 110 of a logical block address range corresponding to an upcoming access operation (e.g., prior to issuing an access command). Memory system 110 may use the logical block address range to load (e.g., pre-load, pre-fetch) an associated portion of a L2P mapping (e.g., from a non-volatile memory device to a volatile memory device) prior to receiving an access command that indicates memory system 110 to perform the access operation. Accordingly, after host system 105 issues the access command, memory system 110 may issue a response to host system 105 faster as memory system 110 has already loaded relevant portions of the L2P mapping associated with the access operation.

The above description of the system diagram 101 are illustrative examples of communication between host system 105 and memory system 110 by using a kernel 107, application 109, and firmware 119. It is understood that additional ways of communication, including function calls, commands, responses, messages, etc. can be implemented using host system 105 and memory system 110, and/or additional systems or components.

FIG. 1C is a simplified block diagram of a memory device 130 in communication with a memory system controller 115 of a memory system (e.g., the memory system 110 of FIGS. 1A and 1B), according to an embodiment. As shown in FIG. 1C and described below in more detail, memory device 130 includes an array of memory cells 104 logically arranged in rows and columns. Memory cells of a logical row are typically connected to the same access line (e.g., a word line) while memory cells of a logical column are typically selectively connected to the same data line (e.g., a bit line). A single access line can be associated with more than one logical row of memory cells and a single data line can be associated with more than one logical column. Memory cells (not shown in FIG. 1C) of at least a portion of the array of memory cells 104 are capable of being programmed to one of at least two target data states for storing any number of bits of information.

With continued reference to FIG. 1C, row decode circuitry 108 and column decode circuitry 111 are provided to decode address signals. Address signals are received and decoded to access the array of memory cells 104. Memory device 130 also includes input/output (I/O) control circuitry 112 to manage input of commands, addresses, and data to memory device 130 as well as output of data and status information from memory device 130. An address register 144 is in communication with I/O control circuitry 112 and row decode circuitry 108 and column decode circuitry 111 to latch the address signals prior to decoding. Row decode circuitry 108 and column decode circuitry 111 may simply be referred to as row decoder 108 and column decoder 111, respectively. A command register 124 is in communication with the I/O control circuitry 112 and local controller 135 to latch incoming commands.

A memory controller (e.g., the local controller 135 internal to memory device 130) controls access to the array of memory cells 104 in response to the commands and generates status information for the external memory system controller 115, i.e., the local controller 135 is configured to perform access operations (e.g., read operations, programming operations, and/or erase operations) on the array of memory cells 104. The local controller 135 is in communication with row decode circuitry 108 and column decode circuitry 111 to control the row decode circuitry 108 and column decode circuitry 111 according to the addresses.

Local controller 135 is also in communication with a cache register 118 and a data register 121. In some embodiments, one or more cache registers 118 can collectively form at least a part of a cache buffer. Cache register 118 latches or buffers data, either incoming or outgoing, as directed by local controller 135 to temporarily store data while the array of memory cells 104 is busy writing or reading, respectively, other data. During a program operation (e.g., write operation), data can be passed from cache register 118 to the data register 121 for transfer to the array of memory cells 104; then new data can be latched in cache register 118 from the I/O control circuitry 112. During a read operation, data can be passed from the cache register 118 to the I/O control circuitry 112 for output to the memory system controller 115; then new data can be passed from the data register 121 to cache register 118. In some embodiments, cache register 118 and/or the data register 121 can form at least a portion of a page buffer 152 of the memory device 130. The page buffer 152 can further include sensing devices such as a sense amplifier, to sense a data state of a memory cell of the array of memory cells 104, e.g., by sensing a state of a data line connected to that memory cell. A status register 122 can be in communication with I/O control circuitry 112 and the local memory controller 135 to latch the status information for output to memory system controller 115.

As shown in FIG. 1C, memory device 130 receives various control signals via local controller 135 from memory system controller 115 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) can be further received over control link 132 depending upon the nature of memory device 130. In one embodiment, memory device 130 receives command signals (which represent commands), address signals (which represent addresses), and data signals (which represent data) from the memory system controller 115 over a multiplexed input/output (I/O) bus 134 and outputs data to the memory system controller 115 over I/O bus 134.

For example, the commands can be received over input/output (I/O) pins [7:0] of I/O bus 134 at I/O control circuitry 112 and can then be written into a command register 124. The addresses can be received over input/output (I/O) pins [7:0] of I/O bus 134 at I/O control circuitry 112 and can then be written into address register 144. The data can be received over input/output (I/O) pins [7:0] for an 8-bit device or input/output (I/O) pins [15:0] for a 16-bit device at I/O control circuitry 112 and then can be written into cache register 118. The data can be subsequently written into data register 121 for programming the array of memory cells 104.

In an embodiment, cache register 118 can be omitted, and the data can be written directly into data register 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the memory system controller 115), such as conductive pads or conductive bumps as are commonly used. While the above description using 16 bits I/O bus 134 as an example, it is understood that bus 134 can be configured to any number of bits (e.g., 64 bits).

It will be appreciated by those skilled in the art that additional circuitry and signals can be provided, and that memory device 130 of FIG. 1C has been simplified. It should be recognized that the functionality of the various block components described with reference to FIG. 1C may not necessarily be segregated to distinct components or component portions of an integrated circuit device. For example, a single component or component portion of an integrated circuit device could be adapted to perform the functionality of more than one block component of FIG. 1C. Alternatively, one or more components or component portions of an integrated circuit device could be combined to perform the functionality of a single block component of FIG. 1C. Additionally, while specific I/O pins are described in accordance with popular conventions for receipt and output of the various signals, it is noted that other combinations or numbers of I/O pins (or other I/O node structures) can be used in the various embodiments.

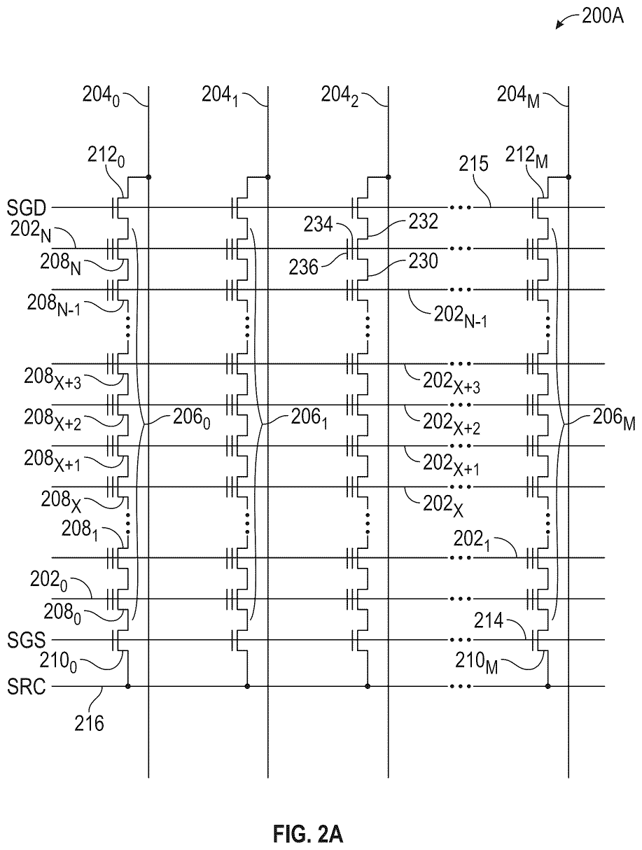

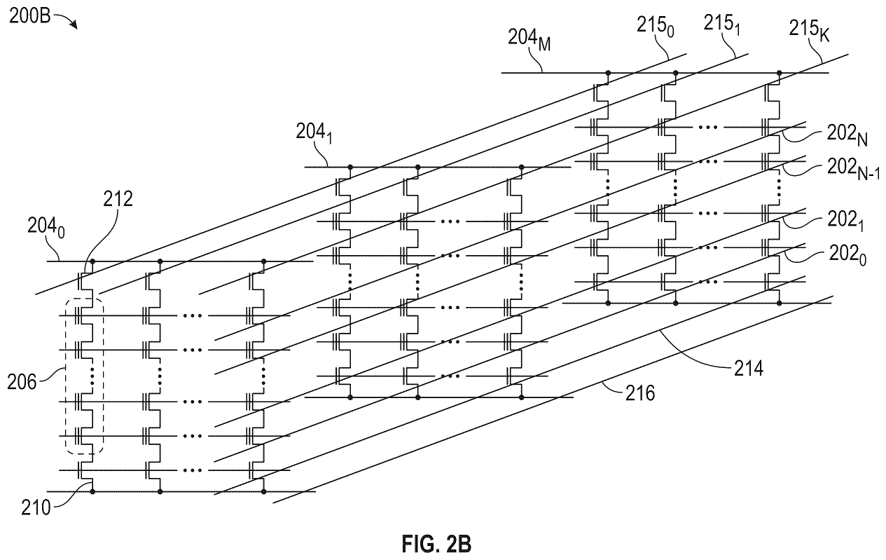

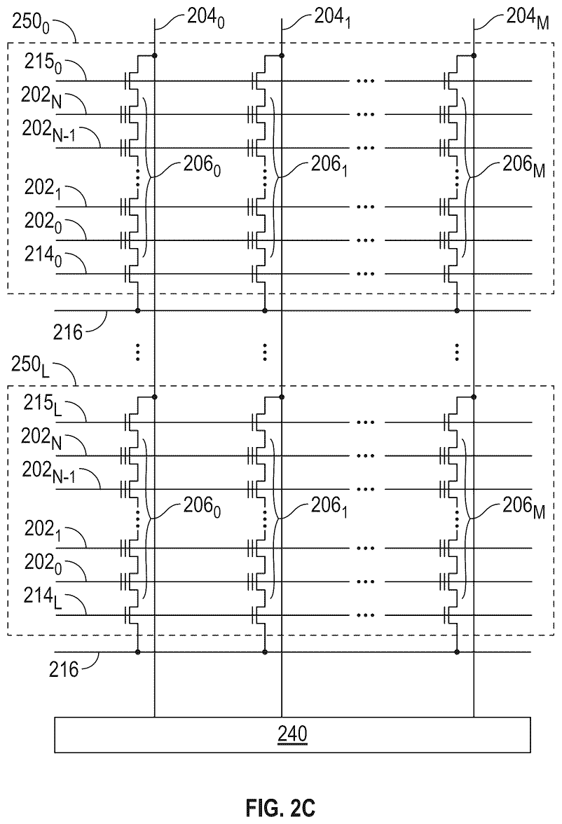

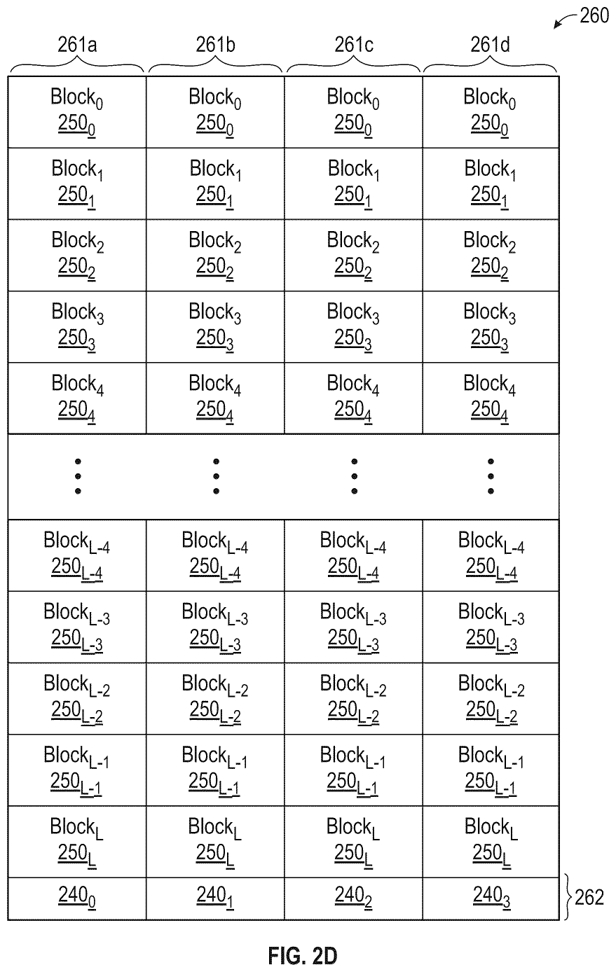

FIGS. 2A-2B are example schematics of portions of an array of memory cells 200A, such as a NAND memory array. Array of memory cells 200A may be an example of memory array 104 of a memory device 130 as described with reference to FIG. 1C according to an embodiment. Memory array 200A includes access lines, such as word lines 202₀ to 202_{N}, and data lines, such as bit lines 204₀ to 204_{M}. The word lines 202 can be connected to global access lines (e.g., global word lines), not shown in FIG. 2A, in a many-to-one relationship. For some embodiments, memory array 200A can be formed over a semiconductor that, for example, can be doped to have a conductive type, such as a p-type conductivity, e.g., to form a p-well, or an n-type conductivity, e.g., to form an n-well.

Memory array 200A can be arranged in rows (each corresponding to a word line 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select gate 210 (e.g., a field-effect transistor), such as one of the select gates 210₀ to 210_{M} (e.g., that can be source select transistors, commonly referred to as select gate source), and a select gate 212 (e.g., a field-effect transistor), such as one of the select gates 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select gates 210 and 212 can utilize a structure similar to (e.g., the same as) the memory cells 208. The select gates 210 and 212 can represent a number of select gates connected in series, with each select gate in series configured to receive a same or independent control signal.

A source of each select gate 210 can be connected to common source 216. The drain of each select gate 210 can be connected to a memory cell 208₀ of the corresponding NAND string 206. For example, the drain of select gate 210₀ can be connected to memory cell 208₀ of the corresponding NAND string 206₀. Therefore, each select gate 210 can be configured to selectively connect a corresponding NAND string 206 to the common source 216. A control gate of each select gate 210 can be connected to select line 214.

The drain of each select gate 212 can be connected to bit line 204 for the corresponding NAND string 206. For example, the drain of select gate 212₀ can be connected to the bit line 204₀ for the corresponding NAND string 206₀. The source of each select gate 212 can be connected to a memory cell 208_{N} of the corresponding NAND string 206. For example, the source of select gate 212₀ can be connected to memory cell 208_{N} of the corresponding NAND string 206₀. Therefore, each select gate 212 can be configured to selectively connect a corresponding NAND string 206 to the corresponding bit line 204. A control gate of each select gate 212 can be connected to select line 215.

The memory array 200A in FIG. 2A can be a quasi-two-dimensional memory array and can have a generally planar structure, e.g., where the common source 216, NAND strings 206 and bit lines 204 extend in substantially parallel planes. Alternatively, the memory array 200A in FIG. 2A can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. Memory cells 208 have their control gates 236 connected to (and in some cases form) a word line 202.

A column of the memory cells 208 can be a NAND string 206 or a number of NAND strings 206 selectively connected to a given bit line 204. A row of memory cells 208 can be memory cells 208 commonly connected to a given word line 202. A row of memory cells 208 can, but need not, include all the memory cells 208 commonly connected to a given word line 202. Rows of memory cells 208 can often be divided into one or more groups of physical pages of memory cells 208, and physical pages of the memory cells 208 often include every other memory cell 208 commonly connected to a given word line 202. For example, the memory cells 208 commonly connected to word line 202_{N} and selectively connected to even bit lines 204 (e.g., bit lines 204₀, 204₂, 204₄, etc.) can be one physical page of the memory cells 208 (e.g., even memory cells) while memory cells 208 commonly connected to word line 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅ are not explicitly depicted in FIG. 2A, it is apparent from the figure that the bit lines 204 of the array of memory cells 200A can be numbered consecutively from bit line 204₀ to bit line 204_{M}. Other groupings of memory cells 208 commonly connected to a given word line 202 can also define a physical page of memory cells 208. For certain memory devices, all memory cells commonly connected to a given word line can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to word lines 202₀-202_{N} (e.g., all NAND strings 206 sharing common word lines 202). Unless expressly distinguished, a reference to a page of memory cells herein refers to the memory cells of a logical page of memory cells. A logical page may or may not be the same as a physical page. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another schematic of a portion of an array of memory cells 200B as could be used in a memory device described with reference to FIG. 1B, e.g., as a portion of the array of memory cells 104. Like numbered elements in FIG. 2B correspond to the description as provided with respect to FIG. 2A. FIG. 2B provides additional detail of one example of a three-dimensional NAND memory array structure. Three-dimensional NAND memory array 200B can incorporate vertical structures which can include semiconductor pillars where a portion of a pillar can act as a channel region of the memory cells of NAND strings 206. NAND strings 206 can be each selectively connected to a bit line 204₀-204_{M} by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bit line 204. Subsets of NAND strings 206 can be connected to their respective bit lines 204 by biasing the select lines 215₀-215_{K} to selectively activate particular select transistors 212 each between a NAND string 206 and a bit line 204. The select transistors 210 can be activated by biasing the select line 214. In some embodiments, each sub-block or string of memory cells has a separate select line 214 from other sub-blocks or strings. In some embodiments, a pair of sub-blocks shares a select line 214. Each word line 202 can be connected to multiple rows of memory cells of the memory array 200B. Rows of memory cells that are commonly connected to each other by a particular word line 202 can collectively be referred to as tiers.

The three-dimensional NAND memory array 200B may include multiple stacked layers of levels of memory cells and connected using vertical channels such as semiconductor pillars. The number of layers in three-dimensional NAND memory array 200B can be, for example, 32, 48, 64, 96, 112 layers, or any number of layers. In some examples, a group of layers may be collectively referred to as a deck. A deck in a three-dimensional NAND memory array may be processed together (e.g., etched together for forming a portion of the semiconductor pillar). A memory device having three-dimensional NAND memory arrays can provide more memory cells on a single chip than a memory device formed by two-dimensional NAND arrays; and therefore provide a higher storage capacity. Furthermore, in a memory device having three-dimensional NAND memory arrays, transistors in memory cells are spaced out, and therefore interference and electron leaks can be reduced.

As described above, memory cells can be grouped into memory blocks. FIG. 2C depicts groupings of NAND strings 206 into blocks of memory cells 250, e.g., blocks of memory cells 250₀-250_{L}. Blocks of memory cells 250 can be groupings of memory cells 208 that can be erased together in a single erase operation. The group of memory cells that can be erased together is also referred to as an erase block. Each block of memory cells 250 can represent those NAND strings 206 commonly associated with a single select line 215, e.g., select line 215₀. The common source 216 for the block of memory cells 250₀ can be a same source as the source 216 for the block of memory cells 250_{L}. For example, each block of memory cells 250₀-250_{L} can be commonly selectively connected to the source 216. Access lines 202 and select lines 214 and 215 of one block of memory cells 250 can have no direct connection to access lines 202 and select lines 214 and 215, respectively, of any other block of memory cells of the blocks of memory cells 250₀-250_{L}.

The bit lines 204₀-204_{M} can be connected (e.g., selectively connected) to a buffer portion 240, which can be a portion of the page buffer 152 of the memory device 130. The buffer portion 240 can correspond to a memory plane (e.g., the set of blocks of memory cells 250₀-250_{L}). The buffer portion 240 can include sense circuits (which can include sense amplifiers) for sensing data values indicated on respective bit lines 204.

FIG. 2D is a block schematic of a portion of an example array of memory cells 260. Array of memory cells 260 can be used as array 104 in a memory device 130 described with reference to FIG. 1C. The array of memory cells 260 is depicted as having four memory planes 261 (e.g., memory planes 261a-261d). Each of the memory planes 261 can correspond to planes 165 depicted in FIG. 1A. Each memory plane 261 can be in communication with a respective buffer portion 240, which can collectively form a page buffer 262. Page buffer 262 may be used to implement page buffer 152 shown in FIG. 1C. While four memory planes 261 are depicted, other numbers of memory planes 261 can be commonly in communication with a page buffer 262. Each memory plane 261 is depicted to include L+1 blocks of memory cells 250 (e.g., blocks of memory cells 250₀-250_{L}).

With continued reference to FIGS. 1C and 2A-2C, during a true erase operation (during which memory cells are actually being erased), the local controller 135 (e.g., using an erase operation manager 137) can cause a common source voltage line, e.g., the SRC 216 (FIG. 2A), to be ramped to an erase voltage (V_{ERA}) with an erase pulse while the select gates 210₀ to 210_{M} (SGS transistors) are turned on. Ramping to this high bias erase voltage, and the subsequent recovery from this voltage ramping, may take a significant amount of time. Concurrently, the erase operation manager 137 can cause the select gates 212₀ to 212ₘ (FIG. 2A) to be turned off to enable the drains of the select gates 212₀ to 212ₘ to float, which causes the bit lines 204₀ to 204_{M} to also float. Further, the erase operation manager 137 can couple the word lines 202 (FIG. 2A) to ground, e.g., zero volts, or retain the word lines 202 at a low voltage. This set of voltage levels at the memory array 200A can create an erase potential that causes the memory cells 208₀ to 208_{N} to be erased, e.g., forces electrons to exit through a body of each memory cell and out the floating bit lines 204₀ to 204_{M}. In other embodiments, the reverse can be done so the select gates 210₀ to 210_{M} are turned off, causing the SRC line 216 to float while the voltage of the bit lines are ramped to Vera while the select gates 212₀ to 212_{M} are turned on. As mentioned earlier, in 3D NAND, one of the channel region, pillar, or bit line can also be ramped up in voltage to cause erasure of attached memory cells. Thus, for simplicity herein, reference to “memory line” should be understood to make reference to any of the SRC line or bit lines in 2D NAND or to any of channel, pillar, or bit lines in 3D NAND. In some embodiments, one or more sub-blocks, to include a physical block, of memory cells are erased during the same true erase operation. A block of memory cells can be generally understood to include four or more sub-blocks, wherein each sub-block includes a separate string of memory cells.

A high-level block diagram of an example apparatus 300 that may be used to implement systems, apparatus, and methods described herein is illustrated in FIG. 3. It is understood that various systems, apparatus, and methods described herein may be implemented using analog and/or digital circuitry, or using one or more computers using well-known computer processors, memory systems, storage devices, computer software, and other components. Typically, a computer includes a processor for executing instructions and one or more memory systems for storing instructions and data. A computer may also include, or be coupled to, one or more mass storage devices, such as one or more magnetic disks, internal hard disks and removable disks, magneto-optical disks, optical disks, etc.

Various systems, apparatus, and methods described herein may be implemented using computers operating in a client-server relationship. Typically, in such a system, the client computers are located remotely from the server computers and interact via a network. The client-server relationship may be defined and controlled by computer programs running on the respective client and server computers. Examples of client computers can include desktop computers, workstations, portable computers, cellular smartphones, tablets, or other types of computing devices.

Various systems, apparatus, and methods described herein may be implemented using a computer program product tangibly embodied in an information carrier, e.g., in a non-transitory machine-readable storage device, for execution by a programmable processor; and the method processes and steps described herein, including one or more of the steps of at least some of the FIGS. 1-18, may be implemented using one or more computer programs that are executable by such a processor. A computer program is a set of computer program instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

As shown in FIG. 3, apparatus 300 may be used to implement a host system (e.g., host system 105 shown in FIG. 1A) that includes, is coupled to, or utilizes a memory system (e.g., memory system 110 of FIG. 1A). Apparatus 300 can be used to perform operations of a controller (e.g., to execute an operating system to perform operations corresponding to host system controller 106 and/or local controller 135 of FIG. 1A).

In some embodiments, apparatus 300 comprises a processor 310 operatively coupled to a data storage device 320 and a main memory device 330. Processor 310 controls the overall operation of apparatus 300 by executing computer program instructions 324 that define such operations. The instructions 324 include instructions to implement functionality of a controller (e.g., host system controller 106 and/or local controller 135 of FIG. 1A). The computer program instructions 324 may be stored in data storage device 320, or other computer-readable medium, and loaded into main memory device 330 when execution of the computer program instructions is desired. For example, processor 310 may be used to implement one or more components and systems described herein, such as host system controller 106 and/or local controller 135 (shown in FIG. 1A). Thus, the method steps of at least some of FIGS. 1-18 can be defined by the computer program instructions 324 stored in main memory device 330 and/or data storage device 320 and controlled by processor 310 executing the computer program instructions 324. For example, the computer program instructions 324 can be implemented as computer executable code programmed by one skilled in the art to perform an algorithm defined by the method steps discussed herein in connection with at least some of FIGS. 1-18. Accordingly, by executing the computer program instructions, processor 310 executes an algorithm defined by the method steps of these aforementioned figures to perform operations (e.g., read, program, erase, etc.). Apparatus 300 also includes one or more network interfaces 380 for communicating with other devices via a network. Apparatus 300 may also include one or more input/output devices 390 that enable user interaction with apparatus 300 (e.g., display, keyboard, mouse, speakers, buttons, etc.).

Processor 310 may include both general and special purpose microprocessors and may be the sole processor or one of multiple processors of apparatus 300. Processor 310 may comprise one or more central processing units (CPUs), and one or more graphics processing units (GPUs), which, for example, may work separately from and/or multi-task with one or more CPUs to accelerate processing, e.g., for various image processing applications described herein. Processor 310, data storage device 320, and/or main memory device 330 may include, be supplemented by, or incorporated in, one or more application-specific integrated circuits (ASICs) and/or one or more field programmable gate arrays (FPGAs).

Data storage device 320 and main memory device 330 each comprise a tangible non-transitory computer readable storage medium. Data storage device 320, and main memory device 330, may each include high-speed random access memory, such as dynamic random access memory (DRAM), static random access memory (SRAM), double data rate synchronous dynamic random access memory (DDR RAM), or other random access solid state memory devices, and may include non-volatile memory, such as one or more magnetic disk storage devices such as internal hard disks and removable disks, magneto-optical disk storage devices, optical disk storage devices, flash memory devices (NAND memory devices, NOR memory devices), semiconductor memory devices, such as erasable programmable read-only memory (EPROM), electrically erasable programmable read-only memory (EEPROM), compact disc read-only memory (CD-ROM), digital versatile disc read-only memory (DVD-ROM) disks, or other non-volatile solid state storage devices. For example, data storage device 320 may be implemented using memory system 110 (FIG. 1A) described herein. In some examples, data storage device 320 and main memory device 330 may include one or more memory devices 130 (FIG. 1A).

Input/output devices 390 may include peripherals, such as a printer, scanner, display screen, etc. For example, input/output devices 390 may include a display device such as a cathode ray tube (CRT), plasma or liquid crystal display (LCD) monitor for displaying information to a user, a keyboard, and a pointing device such as a mouse or a trackball by which the user can provide input to apparatus 300.

Any or all of the functions of the systems and apparatuses discussed herein may be performed by processor 310, and/or incorporated in, an apparatus or a system such as system 100. Further, system 100 and/or apparatus 300 may utilize one or more neural networks or other deep-learning techniques performed by processor 310 or other systems or apparatuses discussed herein.

One skilled in the art will recognize that an implementation of an actual computer or computer system may have other structures and may contain other components as well, and that FIG. 3 is a high-level representation of some of the components of such a computer for illustrative purposes.

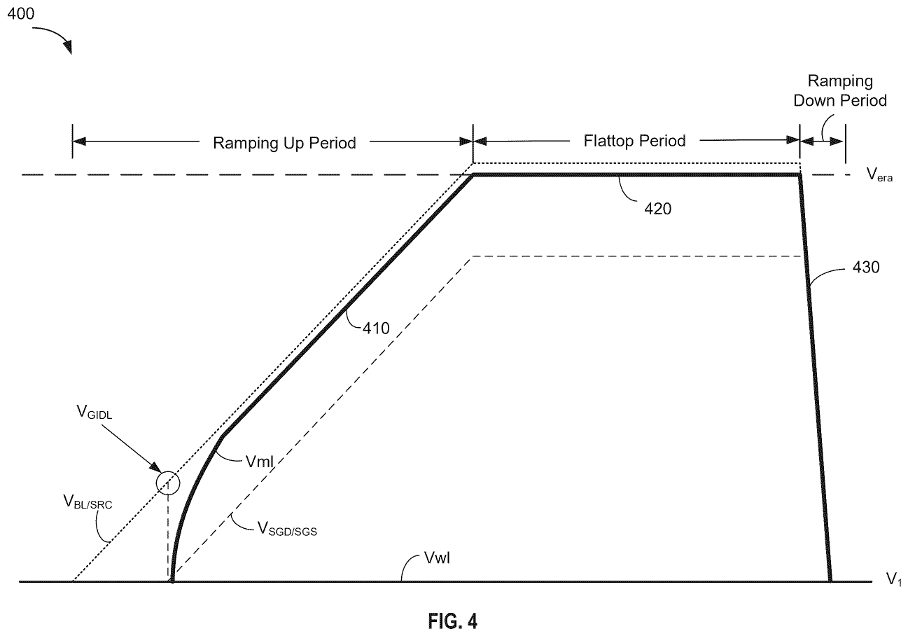

FIG. 4 is a diagram illustrating an example of typical voltage waveforms of an erase pulse 400 for word lines and one or more memory lines (e.g., a memory pillar). A memory device (e.g., memory devices 130 shown in FIG. 1A) comprises a plurality of memory blocks (e.g., memory blocks 170 shown in FIG. 1A). Each of the plurality of memory blocks comprises a plurality of word lines (e.g., word lines 202₀ to 202_{N} shown in FIGS. 2A-2C) and one or more memory lines associated with the plurality of word lines. As described above, a memory line refers to any of the SRC line or bit lines in 2D NAND, or to any of channel, pillar, or bit lines in 3D NAND.

As shown in FIG. 4, in a traditional manner, during an erase operation of a memory block having a plurality of word lines, a voltage of the plurality of word lines (V_{wl}) stays at the first voltage V₁ during the erase pulse 400. The first voltage V₁ is a low voltage. In some embodiments, the first voltage can be a ground voltage (e.g., zero volts), or a small positive or negative voltage. In comparison, in the erase pulse 400, the voltage waveform for the one or more memory lines (Vₘₗ) comprises a ramping up period 410, a flattop period 420, and a ramping down period 430. During the ramping up period 410, the voltage of the memory lines ramps from the first voltage V₁ to an erase voltage Vₑᵣₐ. As described above, the erase voltage Vₑᵣₐ is a high voltage that provides a sufficiently high voltage bias to a string of memory cells to cause the memory cells to be erased. As shown in FIG. 4, the first voltage V₁ is much below the erase voltage Vₑᵣₐ, so that when performing an erase operation, there is a sufficiently high voltage bias between the plurality of word lines and the one or more memory lines associated with the plurality of word lines. As a result, once the memory lines are ramped to the erase voltage Vₑᵣₐ, the data stored in memory cells attached to the memory lines are erased during the flattop period 420. Following erasure of the memory cells, the one or more memory lines can be quickly discharged for a recovery. As shown in FIG. 4, during the ramping down period 430, the voltage of the one or more memory lines (Vₘₗ) ramp quickly down to the first voltage V₁

As shown in FIG. 4, the ramping up period 410 is a relatively long period, in which there is not a substantial erase operation. For example, for an erase pulse 400 that is 2 ms long, the ramping up period 410 can be about 500 us. The ramping rate is limited by gate-induced drain leakage (GIDL) capability and loading. The GIDL effect is a band-to-band tunneling effect. For a semiconductor device, when the band bending at the oxide interface is greater than or equal to the energy band gap of the drain material, electrons in the valence band of the n-type drain tunnel through the thinned band gap into the conduction band, whereas the remaining holes flow into the one or more memory pillars. As shown in FIG. 4, V_{GIDL} is a difference between a voltage of the bit lines and a voltage of the SGD line (i.e., V_{GIDL}=V_{BL}-V_{SGD}) or a difference between a voltage of the SRC line and the SGS line (i.e., V_{GIDL}=V_{SRC}-V_{SGS}). As shown in FIG. 4, assuming the voltage of the bit lines/SRC line (V_{BL/SRC}) and the voltage of the SGD and SGS lines both start at the same low voltage (e.g., 0V), then there are no differences between them. As a result, V_{GIDL} is also zero or very small. When the voltage of the bit lines/SRC lines increases and reaches a threshold voltage (indicated by V_{GIDL} in FIG. 4), the GIDL current is generated, and the memory pillar is charged up. After that, the voltage of the SGD/SGS lines begins to increase at a rate or slope that is the same or similar to that of the bit lines/SRC lines, thereby keeping the GIDL current generation. In FIG. 4, the ramping slope of period 410 is the same as, or similar to, the ramping slope of the voltage of bite lines /SRC lines V_{BL/SRC}. As described above, each of the plurality of memory blocks may comprise a high number of word lines (e.g., a few hundreds word lines). Therefore, the loading may be considerably large. As a result, ramping the one or more memory lines associated with the high number of word lines up to the erase voltage Vₑᵣₐ can take a significant amount of time, which causes a significant erase latency when the erase operation is applied block-by-block. Therefore, there is a need to reduce latency in an erase operation to improve quality of service (QoS).

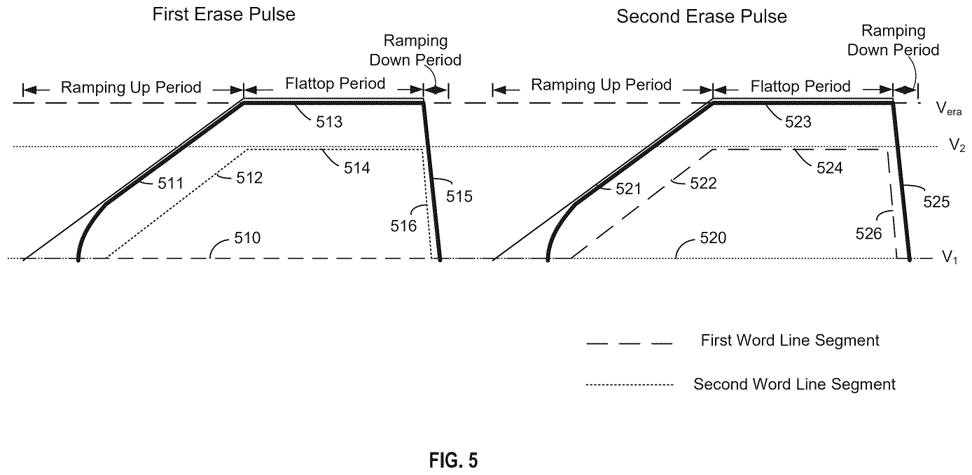

FIG. 5 is a diagram illustrating an example of voltage waveforms for reducing latency in an erase operation in a memory device according to some embodiments. The memory device (e.g., memory devices 130 shown in FIG. 1A) comprises a plurality of memory blocks (e.g., memory blocks 170 shown in FIG. 1A). Each of the plurality of memory blocks comprises a plurality of word line segments. Each of the plurality of word line segments comprises one or more word lines forming a subset of word lines in the memory block. In some embodiments as shown in FIG. 5, the plurality of word line segments is partitioned into two word line segments, e.g., a first word line segment and a second word line segment. In some embodiments, the plurality of word line segments is partitioned into four word line segments, eight word line segments, or any other number of word line segments. As a result, a high number of word lines (e.g., a few hundreds word lines) can be partitioned into the plurality of word line segments, so that a number of word lines in one word line segment is relatively small, thereby reducing the loading for a ramping up.

The memory device further comprises a memory controller (e.g., local controller 135 shown in FIGS. 1A and 1C) configured to control voltages of the plurality of word lines and one or more memory lines associated with the plurality of word lines to perform the erase operation. The memory controller receives an erase command (e.g., from a host system) for erasing data in the memory block. In response to receiving the erase command, the memory controller causes to apply one or more erase pulses to the plurality of word line segments. As shown in FIG. 5, the memory controller causes word lines of different word line segments to ramp up in different time periods, so that when data erasing begins at the first word line segment, data erasing does not begin at the second word line segment. Similarly, when data erasing begins at the second word line segment, data erasing does not begin at the first word line segment. Thus, data erasing can be performed in an alternating manner. As a result, the reduced loading shortens a time of the ramping up period, thereby reducing the latency in the erase operation.

In sone embodiments, for erasing multiple word line segments, a memory controller can apply multiple erase pulses. The memory controller causes to apply each of the multiple erase pulses to a respective word line segment of the plurality of word line segments in a sequential manner. In any time period of the different time periods, data erasing occurs at only one word line segments of the plurality of word line segments. As shown in FIG. 5, there are two erase pulses, e.g., a first erase pulse and second erase pulse. During the first erase pulse, data erasing occurs at the first word line segment. During the second erase pulse, data erasing occurs at the second word line segment.

As shown in the left side of FIG. 5, during the first erase pulse, the memory controller keeps word lines of the first word line segment at a first voltage V₁ (Section 510). The first voltage V₁ is a low voltage, as shown in FIG. 5, below an erase voltage Vₑᵣₐ. In some embodiments, the first voltage can be a ground voltage (e.g., zero volts), a small positive or negative voltage.

As shown in Section 511 of FIG. 5, during a ramping up period of the first erase pulse, the memory controller causes one or more memory lines associated with the plurality of word line segments to ramp up toward the erase voltage Vₑᵣₐ. The erase voltage Vₑᵣₐ is a sufficiently high voltage for erasing data in the memory block. The memory controller also causes word lines of the second word line segment to ramp up toward a second voltage V₂ (Section 512). As shown in FIG. 5, the second voltage V₂ is a voltage higher than the first voltage V₁. In some embodiments, the second voltage may or may not be equal to the erase voltage Vₑᵣₐ. As shown in FIG. 5, the ramping up of the word lines of the second word line segment (Section 512) may be performed together with the ramping up of the one or more memory lines (Section 511). In this scenario of ramping up, the loading with only the word lines of the first word line segment is smaller than that with the word lines of both the first and second word line segments. As a result, the time for the ramping up period is reduced, thereby reducing latency in the erase operation. For example, for a high number of word lines (e.g., a few hundreds word lines in each of the plurality of memory blocks) partitioned into two word line segments, the ramping up period can be reduced from 500 us to 300 us. When the same number of word lines are partitioned into four word line segments, the ramping up period can be reduced to about 200 us. When eight word line segments are used, the ramping up period can be reduce to about 150 us, and so forth.

As shown in FIG. 5, during a flattop period of the first erase pulse, the memory controller keeps the one or more memory lines associated with the plurality of word line segments at approximately the erase voltage Vₑᵣₐ for at least a threshold time period (Section 513), such that data erasing begins at the first word line segment. As shown in FIG. 5, during the flattop period, the memory controller also keeps the word lines of the second word line segment at approximately the second voltage V₂ (Section 514). Because there is not a sufficient high voltage bias in the word lines of the second word line segment, data erasing does not begin at the second word line segment.

As shown in FIG. 5, during a ramping down period of the first erase pulse, the memory controller causes the one or more memory lines associated with the plurality of word line segments to ramp down (Section 515). The memory controller also causes the word lines of the second word line segment to ramp down (Section 516). As a result, the one or more memory lines and the word lines of the second word line segment are discharged for a recovery.

As shown in the right side of FIG. 5, during the second erase pulse, the memory controller keeps word lines of the second word line segment at the first voltage V₁ (Section 520). Similarly, during a ramping up period of the second erase pulse, the memory controller causes one or more memory lines associated with the plurality of word line segments to ramp up toward the erase voltage Vₑᵣₐ (Section 521). Then the memory controller causes word lines of the first word line segment to ramp up toward the second voltage V₂ (Section 522). As shown in FIG. 5, in some embodiments, the ramping up of the word lines of the first word line segment (Section 522) may be performed together with the ramping up of the one or more memory lines (Section 521). Similarly, the loading with only the word lines of the second word line segment is smaller than that with the word lines of both the first and second word line segments. As a result, the time for the ramping up period is reduced, thereby reducing latency in the erase operation.

Similar to the left side of FIG. 5, during a flattop period of the second erase pulse, the memory controller keeps the one or more memory lines associated with the plurality of word line segments at approximately the erase voltage Vₑᵣₐ for at least a threshold time period (Section 523), such that data erasing begins at the second word line segment. The memory controller also keeps the word lines of the first word line segment at approximately the second voltage V₂ during the flattop period (Section 524). Because there is not a sufficiently high voltage bias in the word lines of the first word line segment, data erasing does not begin at the first word line segment.

As shown in FIG. 5, during a ramping down period of the second erase pulse, the memory controller causes the one or more memory lines associated with the plurality of word line segments to ramp down (Section 525). The memory controller also causes the word lines of the first word line segment to ramp down (Section 526). As a result, the one or more memory lines and the word lines of the first word line segment are discharged for a recovery.

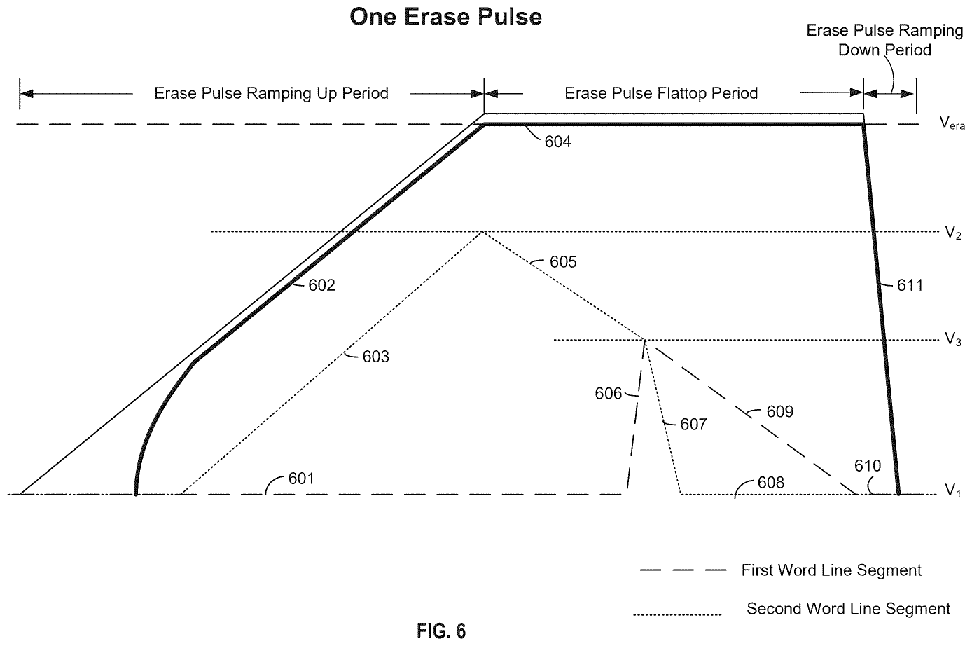

FIG. 6 is a diagram illustrating another example of voltage waveforms for reducing latency in an erase operation in a memory device according to some embodiments. Similar to the memory device in FIG. 5, a memory device (e.g., memory devices 130 shown in FIG. 1A) comprises a plurality of memory blocks (e.g., memory blocks 170 shown in FIG. 1A). Each of the plurality of memory blocks comprises a plurality of word line segments. Each of the plurality of word line segments comprises one or more word lines forming a subset of word lines in the memory block. In some embodiments as shown in FIG. 6, the plurality of word line segments is partitioned into two word line segments, e.g., a first word line segment and a second word line segment. In some embodiments, the plurality of word line segments is partitioned into four word line segments, eight word line segments, or any other number of word line segments. Two word line segments are used for illustrations, but the same or similar method or principle can be applied to other numbers of word line segments.

The memory device further comprises a memory controller (e.g., local controller 135 shown in FIGS. 1A and 1C) configured to control voltages of the plurality of word lines and one or more memory lines associated with the plurality of word lines to perform the erase operation. The memory controller receives an erase command for erasing data in the memory block. In response to receiving the erase command, as shown in FIG. 6, the memory controller causes to apply one erase pulse to the plurality of word line segments. As shown in FIG. 6, during the one erase pulse, the first word line segment and the second word line segment ramp up in different time periods, so that while data erasing begins at the first word line segment, data erasing does not begin at the second word line segment. Similarly, while data erasing begins at the second word line segment, data erasing does not begin at the first word line segment.

In particular, as shown in FIG. 6, during the one erase pulse, the memory controller firstly keeps word lines of the first word line segment at a first voltage V₁ (section 601). The first voltage V₁ is a low voltage, as shown in FIG. 6, below an erase voltage Vₑᵣₐ. In some embodiments, the first voltage can be a ground voltage (e.g., zero volts), or a small positive or negative voltage. As shown in FIG. 6, during an erase pulse ramping up period, the memory controller causes one or more memory lines associated with the plurality of word line segments to ramp up toward an erase voltage Vₑᵣₐ (section 602). The erase voltage Vₑᵣₐ is a sufficiently high voltage for erasing data in the memory block. The memory controller also causes word lines of the second word line segment to ramp up toward a second voltage V₂ (section 603). The second voltage V₂ is a voltage higher than the first voltage V₁. In some embodiments, the second voltage may or may not be equal to the erase voltage Vₑᵣₐ. As shown in FIG. 6, the ramping up of the word lines of the second word line segment may be performed together with the ramping up of the one or more memory lines. In this scenario, the loading with only the word lines of the first word line segment is smaller than that with the word lines of both the first and second word line segments. As a result, the time for the ramping up period is reduced, thereby reducing latency in the erase operation. For example, for a high number of word lines (e.g., a few hundreds word lines in each of the plurality of memory blocks) partitioned into two word line segments, the ramping up period can be reduced from 500 us to 300 us.

As shown in FIG. 6, during an erase pulse flattop period, the memory controller keeps the one or more memory lines associated with the plurality of word line segments at approximately the erase voltage Vₑᵣₐ (section 604), such that data erasing begins at the first word line segment. During the erase pulse flattop period, while the word lines of the first word line segment are kept at first voltage V₁, the memory controller causes the word lines of the second word line segment to ramp down toward a third voltage V₃ (section 605). The third voltage V₃ is a voltage higher than the first voltage V₁ and lower than the second voltage V₂. During this period, data erasing occurs at only the first word line segment. In contrast, because there is not a sufficient high voltage bias in the word lines of the second word line segment, data erasing does not begin at the second word line segment.

As shown in FIG. 6, the memory controller further causes the voltage of the word lines of the first word line segment to ramp up toward the third voltage V₃ (section 606). Then the memory controller causes the word lines of the second word line segment to continue to ramp down toward approximately the first voltage V₁ (section 607). In this scenario, in order to ramp down the word lines of the second word line segment fast (as shown in FIG. 6, a ramping slope of section 607 is much steeper than a ramping slope of section 605), charges stored between the word lines of the first word line segment and the one or more memory lines are moved to between the word lines of the second word line segment and the one or more memory lines.

As shown in FIG. 6, after the voltage of the word lines of the second word line segment ramps down to approximately the first voltage V₁, the memory controller keeps the word lines of the second word line segment at approximately the first voltage V₁ (section 608), such that data erasing begins at the second word line segment. In some embodiments, the memory controller also causes the voltage of the word lines of the first word line segment to ramp down toward approximately the first voltage V₁ (section 609). As shown in FIG. 6, due to the charge movement, a slope for ramping down the word lines of the first word line segment (section 609) can be the same as a slope for ramping down the word lines of the second word line segment (section 605). As shown in the section 610 of the FIG. 6, the memory controller keeps the word lines of the second word line segment at approximately the first voltage V₁, such that data erasing may occur again at the first word line segment. As shown in the section 604, during the erase pulse flattop period of the one erase pulse, the memory controller can keep the one or more memory lines associated with the plurality of word line segments at approximately the erase voltage Vₑᵣₐ for a sufficient time period for data erasing at the first word line segment and at the second word line segment to complete.

Finally, during an erase pulse ramping down period, the memory controller causes the one or more memory lines associated with the plurality of word line segments to ramp down (Section 611). As a result, the one or more memory lines are discharged for a recovery.

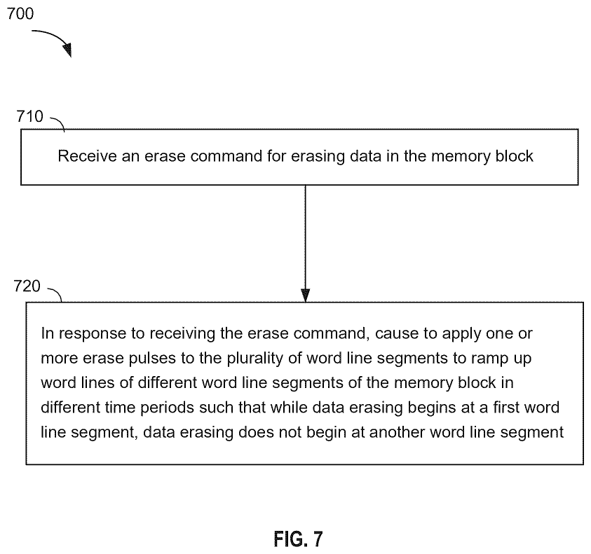

FIG. 7 shows a flowchart illustrating an example method 700 for reducing latency in an erase operation in a memory device according to some embodiments. The memory device (e.g., memory devices 130 shown in FIG. 1A) comprises a plurality of memory blocks (e.g., memory blocks 170 shown in FIG. 1A). Each of the plurality of memory block comprises a plurality of word line segments. Each of the plurality of word line segments comprises one or more word lines forming a subset of word lines in the memory block. In some embodiments, the plurality of word line segments is partitioned into two word line segments, four word line segments, eight word line segments, or any number of word line segments.

The memory device further comprises a memory controller (e.g., local controller 135 shown in FIGS. 1A and 1C) configured to control voltages of the plurality of word lines and one or more memory lines associated with the plurality of word lines to perform the erase operation. In block 710 of method 700, the memory controller receives an erase command (e.g., from a host system) for erasing data in a memory block.

In block 720 of method 700, in response to receiving the erase command, the memory controller causes to apply one or more erase pulses to the plurality of word line segments. The memory controller causes word lines of different word line segments of the memory block to ramp up in different time periods, such that while data erasing begins at a first word line segment, data erasing does not begin at another word line segment. As a result, a high number of word lines (e.g., a few hundreds word lines) are partitioned into the plurality of word line segments, and when ramping up word lines of different word line segments in different time periods, a loading for the each ramping up are reduced. Therefore, the reduced loading shortens the time of the ramping up period, thereby reducing latency in the erase operation.

In sone embodiments, the one or more erase pulses comprise multiple erase pulses. The memory controller causes to apply the multiple erase pulses to the plurality of word line segments to ramp up word lines of different word line segments of the memory block in different time periods. The memory controller causes to apply each of the multiple erase pulses to a respective word line segment of the plurality of word line segments in a sequential manner, such that in any time period of the different time periods, data erasing occurs at only one word line segments of the plurality of word line segments.

In sone embodiments, the one or more erase pulses comprise multiple erase pulses. The memory controller causes to apply a first erase pulse of the multiple erase pulses to two or more word line segments of the plurality of word line segments, such that data erasing of the two or more word line segments begins in the first erase pulse. Subsequent to applying the first erase pulse, the memory controller further applies one or more additional erase pulses to one or more other word line segments of the plurality of word line segments, such that data erasing of the one or more other word line segments begins in the respective one or more additional erase pulses.

In sone embodiments, the one or more erase pulses comprise a single erase pulse. The memory controller causes to apply the single erase pulses to the plurality of word line segments to ramp up word lines of different word line segments of the memory block in different time periods. During the single erase pulse, the memory controller causes memory lines of the plurality of word line segments to ramp up toward an erase voltage. The erase voltage is a sufficiently high voltage for erasing the data in the memory block. In any time period of the different time periods for ramping up word lines of different word line segments, the memory controller keeps word lines of only one of the plurality of word line segments at a first voltage. The first voltage is a low voltage below the erase voltage. In some embodiments, the first voltage can be a ground voltage (e.g., zero volts), a small positive or negative voltage. The memory controller causes word lines of other word line segments of the plurality of word line segment to ramp up toward a second voltage higher than the first voltage.

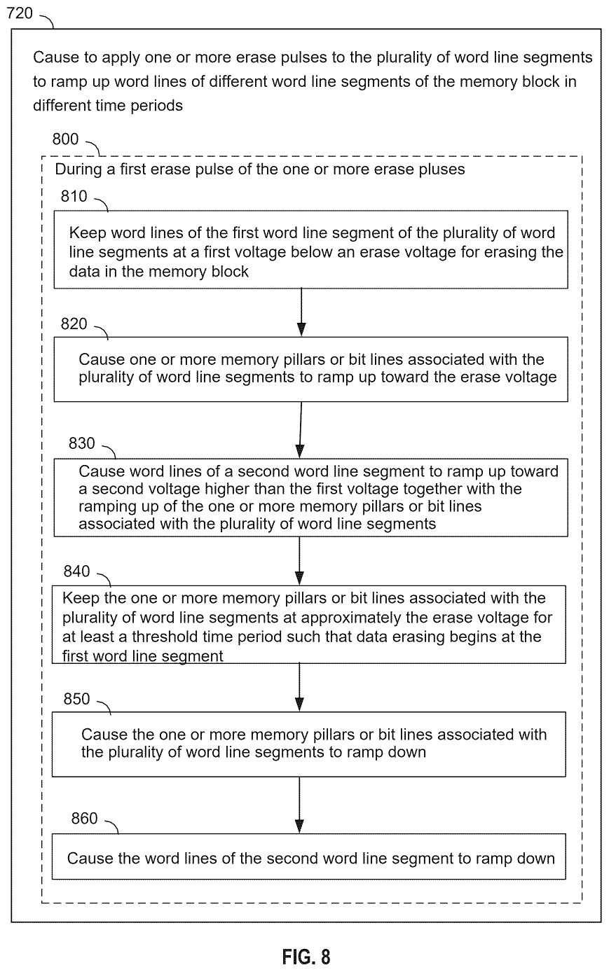

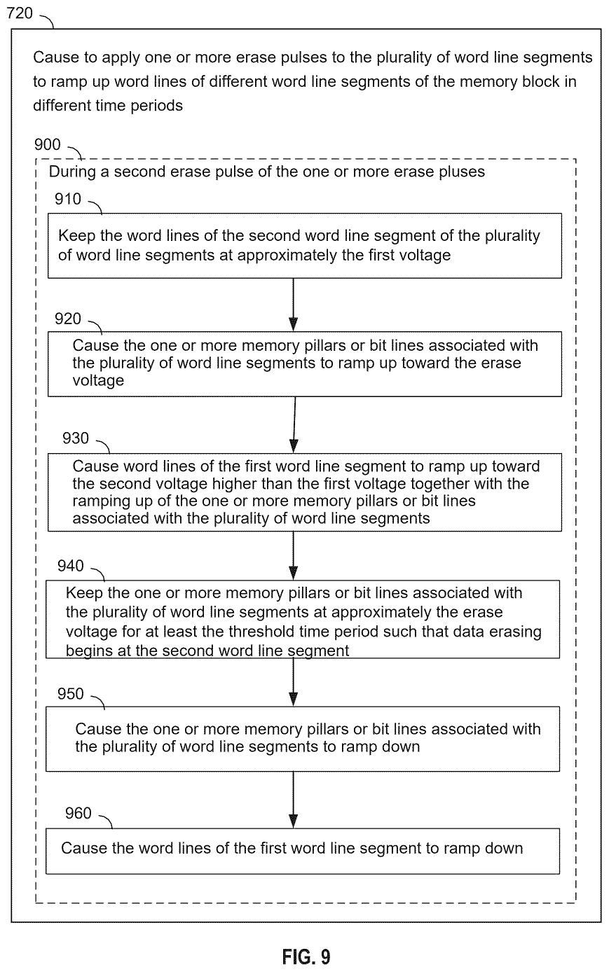

FIGS. 8 and 9 show flowcharts illustrating an example method 720 for ramping up word lines of different word line segments in different time periods according to some embodiments. The block 720 in FIGS. 8 and 9 is the same block 720 in FIG. 7. In block 720, the memory controller causes to apply one or more erase pulses to the plurality of word line segments to ramp up word lines of different word line segments of the memory block in different time periods. As shown in FIGS. 8 and 9, the plurality of word line segments comprises a first word line segment and a second word line segment. In some embodiments, a number of the plurality of word line segments is greater than two. As shown in FIGS. 8 and 9, the memory controller causes to apply each of the multiple erase pulses to a respective word line segment of the plurality of word line segments in a sequential manner, such that in any time period of the different time periods, data erasing occurs at only one word line segments of the plurality of word line segments. As shown in FIGS. 8 and 9, the one or more erase pulses comprises a first erase pulse and a second erase pulse. During the first erase pulse, data erasing occurs at only the first word line segment. During the second erase pulse, data erasing occurs at only the second word line segment.

FIG. 8 illustrates an example method 800 for applying the first erase pulses of the one or more erase pulses to the plurality of word line segments according to some embodiments. In block 810 of method 800, during the first erase pulse, the memory controller keeps word lines of the first word line segment of the plurality of word line segments at a first voltage. The first voltage is a low voltage. In some embodiments, the first voltage can be a ground voltage (e.g., zero volts), a small positive or negative voltage.

In block 820 of method 800, the memory controller causes one or more memory lines associated with the plurality of word line segments to ramp up toward an erase voltage. The erase voltage is a sufficiently high voltage for erasing data in the memory block. The first voltage is below the erase voltage.

In block 830 of method 800, the memory controller causes word lines of the second word line segment to ramp up toward a second voltage. The second voltage is a voltage higher than the first voltage. In some embodiments, the second voltage may or may not be equal to the erase voltage. The ramping up of the word lines of the second word line segment is together with the ramping up of the one or more memory lines. In this scenario, the loading with only the word lines of the first word line segment is reduced than that with both the word lines of the two word line segments. As a result, the time for the ramping up period is reduced, thereby reducing latency in the erase operation.

In block 840 of method 800, the memory controller keeps the one or more memory lines associated with the plurality of word line segments at approximately the erase voltage for at least a threshold time period, such that data erasing begins at the first word line segment. During the threshold time period, the memory controller also keeps the word lines of the second word line segment at approximately the second voltage. Because there is not a sufficient high voltage bias in the word lines of the second word line segment, data erasing does not begin at the second word line segment.

In block 850 of method 800, the memory controller causes the one or more memory lines associated with the plurality of word line segments to ramp down. As a result, the one or more memory lines are discharged for a recovery.

In block 860 of method 800, the memory controller causes the word lines of the second word line segment to ramp down. As a result, the word lines of the second word line segment are discharged for a recovery.

FIG. 9 illustrates an example method 900 for applying the second erase pulses of the one or more erase pulses to the plurality of word line segments according to some embodiments. In block 910 of method 900, during the second erase pulse, the memory controller keeps word lines of the second word line segment of the plurality of word line segments at approximately the first voltage.

In block 920 of method 900, the memory controller causes one or more memory lines associated with the plurality of word line segments to ramp up toward the erase voltage.

In block 930 of method 900, the memory controller causes word lines of the first word line segment to ramp up toward the second voltage. The ramping up of the word lines of the first word line segment is together with the ramping up of the one or more memory lines associated with the plurality of word line segments. Similarly, the loading with only the word lines of the second word line segment is smaller than that with both the word lines of the two word line segments. As a result, the time for the ramping up period is reduced, thereby reducing latency in the erase operation.

In block 940 of method 900, the memory controller keeps the one or more memory lines associated with the plurality of word line segments at approximately the erase voltage for at least a threshold time period, such that data erasing begins at the second word line segment. During the threshold time period, the memory controller also keeps the word lines of the first word line segment at approximately the second voltage. Similarly, because there is not a sufficient high voltage bias in the word lines of the first word line segment, data erasing does not begin at the first word line segment.

In block 950 of method 900, the memory controller causes the one or more memory lines associated with the plurality of word line segments to ramp down. As a result, the one or more memory lines are discharged for a recovery.

In block 960 of method 900, the memory controller causes the word lines of the first word line segment to ramp down. As a result, the word lines of the first word line segment are discharged for a recovery.

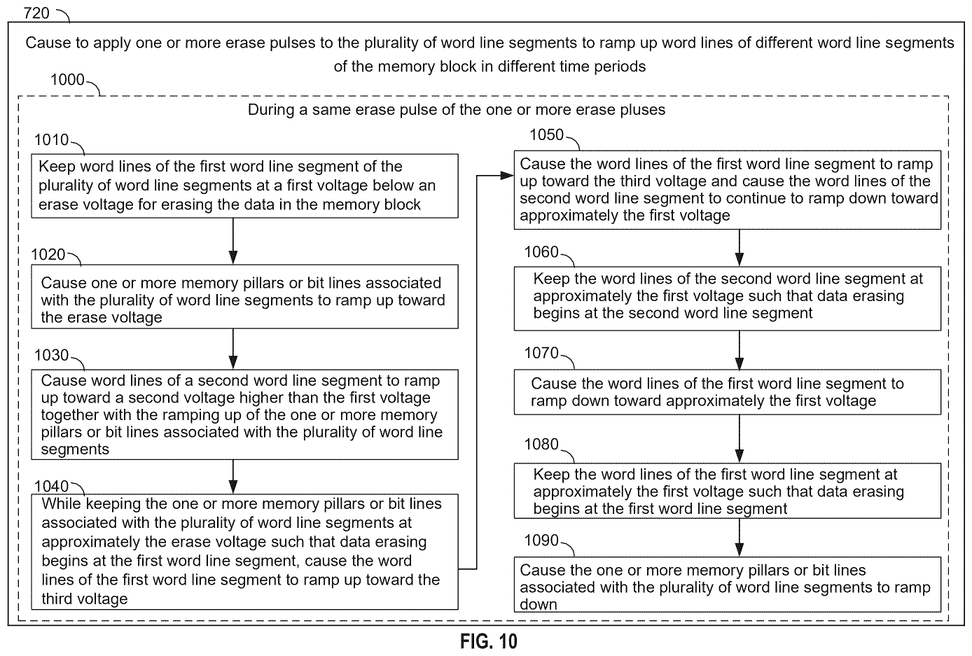

FIG. 10 show a flowchart illustrating another example method 720 for applying one or more erase pulses to the plurality of word line segments to ramp up word lines of different word line segments in different time periods according to some embodiments. The block 720 in FIG. 10 is the same block 720 in FIG. 7. A memory controller causes to apply one or more erase pulses to the plurality of word line segments to ramp up word lines of different word line segments of the memory block in different time periods. FIG. 10 illustrates an example method 1000 for applying a same erase pulse of the one or more erase pulses to the plurality of word line segments. As shown in FIG. 10, the plurality of word line segments comprises a first word line segment and a second word line segment. In some embodiment, for erasing data in the memory block, the plurality of word line segments is partitioned into two word line segments, four word line segments, eight word line segments, or any number of word line segments.

In block 1010 of method 1000, during the same erase pulse of the one or more erase pulses, the memory controller firstly keeps word lines of the first word line segment of the plurality of word line segments at a first voltage. The first voltage is a low voltage. In some embodiments, the first voltage can be a ground voltage (e.g., zero volts), or a small positive or negative voltage.

In block 1020 of method 1000, the memory controller causes one or more memory lines associated with the plurality of word line segments to ramp up toward an erase voltage. The erase voltage is a sufficiently high voltage for erasing the data in the memory block. The first voltage is below the erase voltage.

In block 1030 of method 1000, the memory controller causes word lines of the second word line segment to ramp up toward a second voltage. The second voltage is a voltage higher than the first voltage. In some embodiments, the second voltage may or may not be equal to the erase voltage. The ramping up of the second word line segment is together with the ramping up of the one or more memory lines associated with the plurality of word line segments. In this scenario, the loading with only the word lines of the first word line segment is reduced than that with both the word lines of the two word line segments. As a result, the time for the ramping up period is reduced, thereby reducing latency in the erase operation.

In block 1040 of method 1000, while keeping the one or more memory lines associated with the plurality of word line segments at approximately the erase voltage, such that data erasing begins at the first word line segment, the memory controller causes the word lines of the second word line segment to ramp down toward a third voltage. The third voltage is a voltage higher than the first voltage and lower than the second voltage.

In block 1050 of method 1000, the memory controller causes the word lines of the first word line segment to ramp up toward the third voltage. The memory controller also causes the word lines of the second word line segment to continue to ramp down toward approximately the first voltage. In this scenario, in order to ramp down the word lines of the second word line segment fast, there is charges stored between the word lines of the second word line segment and the one or more memory lines moved to between the word lines of the first word line segment and the one or more memory lines.

In block 1060 of method 1000, the memory controller keeps the word lines of the second word line segment at approximately the first voltage such that data erasing begins at the second word line segment.

In block 1070 of method 1000, the memory controller causes the word lines of the first word line segment to ramp down toward approximately the first voltage. In some embodiments, a slope for ramping down the word lines of the first word line segment from the third voltage to the first voltage is the same as a slope for ramping down the word lines of the second word line segment from the second voltage to the third voltage.

In block 1080 of method 1000, the memory controller keeps the word lines of the first word line segment at approximately the first voltage such that data erasing begins at the first word line segment.

In block 1090 of method 1000, the memory controller causes the one or more memory lines associated with the plurality of word line segments to ramp down. As a result, the one or more memory lines are discharged for a recovery.

In some embodiments, during the same erase pulse, the memory controller keeps the one or more memory lines associated with the plurality of word line segments at approximately the erase voltage for a sufficient time period for data erasing at the first word line segment and at the second word line segment to complete.

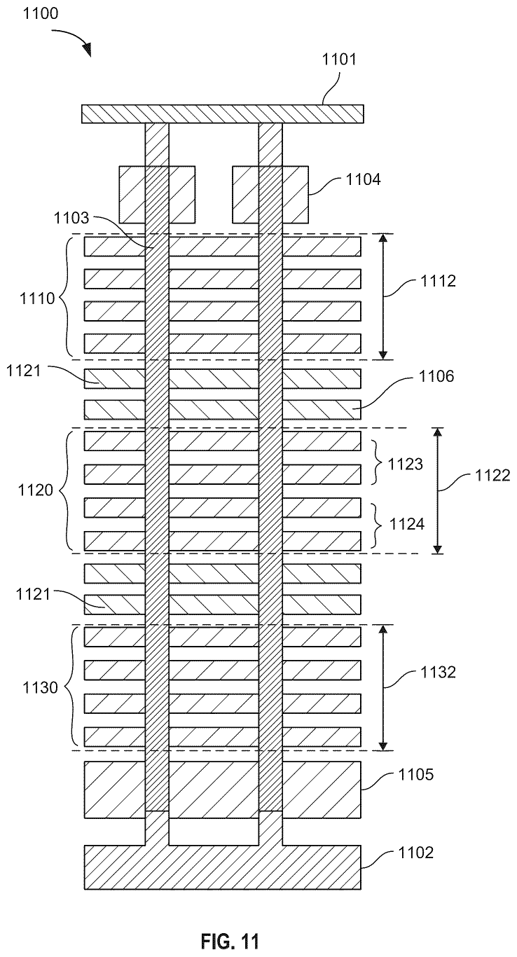

As described above, weak GIDL effect in a 3D memory device may cause an erroneous erase operation or impact the reliability of the memory device. Technologies for boosting an isolated memory pillar portion to mitigate or eliminate the weak GIDL effect in a memory block are now described. FIG. 11 is a diagram illustrating an example of a memory block 1100 comprising one or more word line groups according to some embodiments. As shown in FIG. 11, the memory block 1100 comprises a bit line 1101, a common source (SRC) line 1102, one or more memory pillars 1103, a drain select (SGD) line 1104, and a source select (SGS) line 1105. As shown in FIG. 11, the memory block 1100 further comprises a plurality of word lines 1106. Multiple word lines 1106 can form one or more word line groups in the memory block 1100. FIG. 11 only illustrates three word line groups 1110, 1120, and 1130 in the memory block 1100, but it is understood that more or fewer word line groups can be included. The memory block 1100 further comprises one or more interface word lines 1121 located between two neighboring word line groups. As shown in FIG. 11, interface word lines 1121 are located between the groups 1110 and 1120, or between the groups 1120 and 1130. In some cases, a group of word lines 1106 may be collectively referred to as a deck. A deck in a three-dimensional NAND memory array may be processed together (e.g., etched together for forming a portion of the semiconductor pillar). As shown in FIG. 11, the three word lines groups 1110, 1120, and 1130 can also be referred as a top deck 1110, a middle deck 1120, and a bottom deck 1130, respectively. Accordingly, the memory pillar includes three memory pillar portions 1112, 1122, and 1132 associated with the three word line groups 1110, 1120, and 1130, respectively. While in FIG. 11, a deck corresponds to a word line group, a word line group may include more word lines or fewer word lines in a deck. That is, in a word line group, there may be pillar portions that are not formed in a same etch process. In some embodiments, each of the word line groups further comprises a plurality of word line segments. In some embodiments, a word line segment may include word lines that are more than, or fewer than, word lines in a word line group. As shown in FIG. 11, the word line group (middle deck 1120) further comprises two word line segments 1123 and 1124. When the memory block 1100 performs an erase operation, different voltages can be applied to different word line groups. The erase operation can be performed on different word line groups or segments in different time periods.

The memory block 1100 further comprises a memory controller (e.g., local controller 135 shown in FIGS. 1A and 1C) configured to control voltages to perform an erase operation. As described above, the erase operation is affected by GIDL. The GIDL may introduce many holes with positive charges, and they can be introduced in the memory pillar 1103. As described above, interface portions (e.g., portions associated with the interface word lines 1121) of the memory pillar 1103 may have a weaker GIDL effect (e.g., due to variations of the doping process in manufacturing). The weaker GIDL effect in the interface portions of memory pillar 1103 may cause a voltage of certain portions of the memory pillar (e.g., the memory pillar portion 1122 associated with the middle deck 1120) to be lower than an applied voltage to the bit line 1101 or the SRC line 1102, which makes the erase operation less effective. For example, the memory controller applies an erase voltage Vₑᵣₐ of 20 V to the bit line 1101 and the SRC line 1102. However, a memory pillar portion of the memory pillar 1103 having electronics holes may get only a voltage of 18 V, which is lower than the applied erase voltage Vₑᵣₐ of 20 V. As a result, there is not a sufficient high voltage to perform the erase operation. One way to deal with the weaker GIDL effect in the interface portions is to apply an increased voltage to the bit line 1101 and the SRC line 1102. The increased voltage is higher than the erase voltage Vₑᵣₐ to compensate for the loss of voltage in certain memory pillar portions. However, this causes other problems, e.g., a memory device with a small scale or feature size cannot withstand such a high voltage. Therefore, there is a need for a method to reduce the maximum erase voltage to fit to the current small scale of the memory device, while still enabling the erase operation to be performed properly.

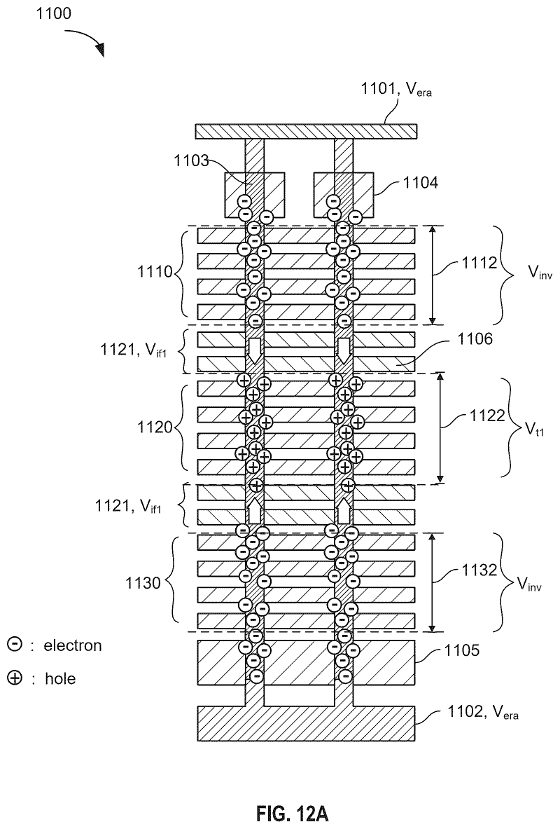

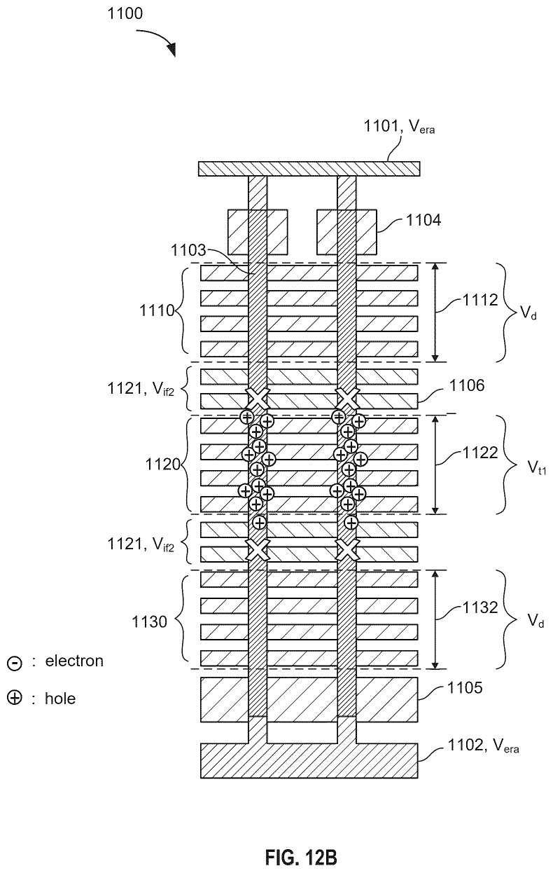

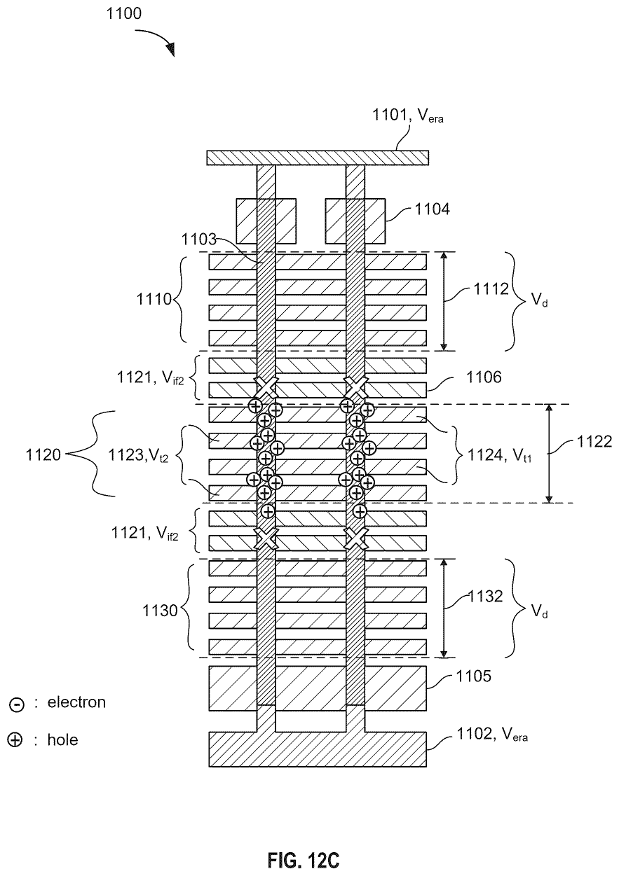

FIGS. 12A-12C show diagrams illustrating an example method for reducing a maximum erase voltage in an erase operation in a memory device according to some embodiments. The memory device (e.g., memory devices 130 shown in FIG. 1A) comprises a plurality of memory blocks (e.g., memory blocks 170 shown in FIG. 1A, and memory block 1100 shown in FIG. 11). The memory device further comprises a memory controller (e.g., local controller 135 shown in FIGS. 1A and 1C) configured to control voltages in each of the plurality of memory blocks to perform the erase operation. FIGS. 12A-12C shows a same memory block 1100 as shown FIG. 11.

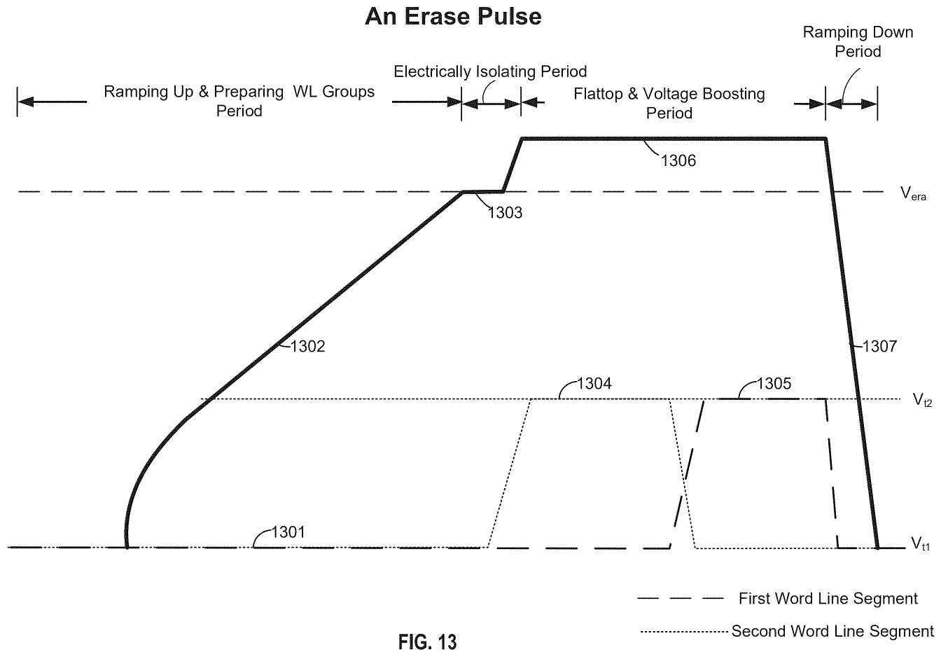

FIGS. 12A-12C illustrate a method to boost the voltage of the memory pillar portion 1122 associated with the middle deck. Boosting of the voltage of the memory pillar portion 1122 reduces the maximum erase voltage required for the erase operation to be performed properly. In one embodiment, the memory controller receives an erase operation command for erasing data in the memory block 1100. In response to receiving the erase operation command, the memory controller selects a target word line group for (1) preparing isolation (illustrated in FIG. 12A), (2) electrical isolating a memory pillar portion associated with the target word line group (illustrated in FIG. 12B), and (3) boosting a voltage of the memory pillar portion associated with the target word line group (illustrated in FIG. 12C). After boosting a voltage of an isolated memory pillar portion associated with the target word line group, the target word line group can perform the erase operation (illustrated in FIG. 13) by using a voltage the same as or less than an erase voltage, thereby reducing the maximum erase voltage in the erase operation.

The above-described steps are now described in more detail. With reference to FIG. 12A first, the memory controller selects the word line group 1120 (e.g., corresponding to the middle deck) as the target word line group. The word line groups 1110 and 1130 are other word line groups neighboring the target word line group 1120. The memory pillar portion 1122 is the memory pillar portion associated with the target word line group 1120. In some embodiments, the memory controller can also select the top deck 1110, or the bottom deck 1130 as a target word line group.

FIG. 12A shows a diagram illustrating an example of preparing for electrical isolation of a memory pillar portion associated the target word line group 1120 according to some embodiments. As shown in FIG. 12A, the memory controller applies an erase voltage Vₑᵣₐ to the bit line 1101 and SRC line 1102. For example, the erase voltage Vₑᵣₐ can be 20 V. As a result, the memory pillar 1103 receives the erase voltage Vₑᵣₐ of 20 V. The memory controller applies an inversion voltage Vᵢₙᵥ to the word lines of the other word line groups 1110 and 1130 neighboring the target word line group 1120. In some embodiment, the inversion voltage Vᵢₙᵥ is sufficiently greater than the erase voltage Vₑᵣₐ to cause channel inversion in the other word line groups 1110 and 1130. For example, the inversion voltage Vᵢₙᵥ can be 25 V for the other word line groups (top deck) 1110 and (bottom deck) 1130. As shown in FIG. 12A, because the voltage differences between the other word line groups 1110 and 1130 (e.g., Vᵢₙᵥ=25 V) and the memory pillar 1103 (e.g., Vₑᵣₐ=20 V) are greater than a threshold voltage, electrons are induced in the memory pillar portions 1112 and 1132 (e.g., the channel region) associated with the other word line groups 1110 and 1130, respectively. As a result, a channel inversion is induced.

As shown in FIG. 12A, the interface word lines 1121 are located between the target word line group 1120 and the other word line group 1110 or 1130. The memory controller further applies a first interface voltage V_{if1} to one or more interface word lines 1121. The first interface voltage V_{if1} is sufficiently less than the erase voltage Vₑᵣₐ to supply holes to the memory pillar portion 1122 of the target word line group 1120. For example, the first interface voltage V_{if1} can be 8 V. The memory controller applies a first target word line voltage Vₜ₁ to the word lines of the target word line group (middle deck) 1120. For example, the first target word line voltage Vₜ₁ can be 0 V. As shown in FIG. 12A, because of voltage difference between the target word line group 1120 (Vₜ₁=0 V) and the memory pillar 1103 (Vₑᵣₐ=20 V), a strong electric field is generated. As a result, holes are induced and located in the memory pillar portions 1122 (e.g., channel region) associated with the target word line group 1120.

Turning to FIG. 12B, it shows a diagram illustrating an example of electrically isolating the memory pillar portion 1122 associated with the target word line group 1120 from the memory pillar portions 1112 and 1132 according to some embodiments. As shown in FIG. 12B, the memory controller applies a depletion voltage V_{d} to the word lines of the other word line groups 1110 and 1130. In some embodiments, the depletion voltage V_{d} is sufficient to cause channel depletion in the other word line groups 1110 and 1130. For example, the depletion voltage V_{d} can be 20 V for the other word line groups (top deck) 1110 and (bottom deck) 1130. When channel depletion occurs, electrons in the memory pillar portions 1112 and 1132 are depleted as shown in FIG. 12B. The channel depletion blocks electrons in bit line 1101 or SRC line 1102 from moving into the memory pillar 1103.

The memory controller further applies a second interface voltage V_{if2} to the interface word lines 1121. In some embodiments, the second interface voltage V_{if2} is sufficient to cause channel depletion or inversion in the interface word lines 1121. For example, the second interface voltage V_{if2} can be 25 V. As shown in FIG. 12B, the electrons are depleted in the memory pillar portions 1112 and 1132 associated with the other word line groups 1110 and 1130, respectively. The channel depletion or inversion in the interface word lines 1121 also blocks holes in the memory pillar portion 1122 from moving out. As a result, the memory pillar portion 1122 associated with the target word line group 1120 is electrically isolated from the memory pillar portions 1112 and 1132 associated with the other word line groups 1110 and 1130, respectively.

In some embodiments, the isolated memory pillar portion 1122 associated with the target word line group 1120 forms at least a part of a n-p-n-p structure with one or more of: other memory pillar portions 1112 and 1132, bit line 1101, SRC line 1102, and interface word lines 1121. For example, the memory controller selects word line group 1120 (e.g., the middle deck) as the target word line group. In this scenario, bit line 1101 and SRC line 1102 are n-type. To block electrons in bit line 1101 or SRC line 1102 from moving into the memory pillar 1103, the memory pillar portions 1112 and 1132 are in depletion or in p-type. To block holes in the memory pillar portion 1122 from moving out, the pillar portion of one or more interface word lines 1121 are in depletion or in n-type. The isolated memory pillar portion 1122 associated with the target word line group 1120 is in p-type. Then a voltage of the memory pillar portion 1122 can be boosted to be the same or even greater than the erase voltage (e.g., the voltage applied to the bit line 1101 or SRC line 1102). In summary, in FIGS. 11 and 12A-12C, an n-p-n-p structure is formed by the bit line 1101, memory pillar portion 1112, pillar portions of the interface word lines 1121, and pillar portion 1122. Similarly, an n-p-n-p structure is also formed by the SRC line 1102, memory pillar portion 1132, pillar portion of the interface word lines 1121, and pillar portion 1122.

After isolation, the memory pillar portion 1122 associated with the target word line group 1120 can be boosted. FIG. 12C shows a diagram illustrating an example method of boosting a voltage of the isolated memory pillar portion 1122 associated with the target word line group 1120 according to some embodiments. As shown in FIG. 12C, the target word line group 1120 further comprises a plurality of word line segments 1123 and 1124. In some embodiments, the word lines of different word line segments can have different voltages. As shown in FIG. 12C, the memory controller applies a second target word line voltage Vₜ₂ to word lines of the word line segment 1123 of the target word line group 1120. The memory controller keeps word lines of the word line segment 1124 at the first target word line voltage Vₜ₁. In some embodiments, the second target word line voltage Vₜ₂ is greater than the first target word line voltage Vₜ₁. For example, the second target word line voltage Vₜ₂ can be 8 V, while the first target word line voltage Vₜ₁ is 0V. By applying the second target word line voltage Vₜ₂ to some of the word lines of the target word line group 1120, the voltage of the memory pillar portion 1122 can be boosted to be the same or even greater than the erase voltage. For example, if the erase voltage Vₑᵣₐ is 20V, the voltage of the memory pillar portion 1122 can be 20V, 22V, or even higher. With the boosted voltage, the memory controller can properly perform an erase operation of the target word line group 1120 without increasing the erase voltage. For example, the erase operation can be performed using a voltage that is the same as or less than the erase voltage Vₑᵣₐ, thereby reducing the maximum erase voltage in the erase operation.

FIG. 13 shows a diagram illustrating an example of performing an erase operation, with the boost of the voltage at a memory pillar portion of the target word line group, for a plurality of word line segments in different time periods according to some embodiments. A memory device (e.g., memory devices 130 shown in FIG. 1A) comprises a plurality of memory blocks (e.g., memory blocks 170 shown in FIG. 1A, and memory block 1100 shown in FIG. 11). Each of the plurality of memory blocks comprises one or more word line groups (e.g., word line groups 1110, 1120, and 1130 shown in FIGS. 11 and 12A-12C). Each of the one or more word line groups comprises a plurality of word line segments (e.g., word line segments 1123 and 1124 shown in FIGS. 11 and 12C) including multiple word lines (word lines 1106 shown in FIGS. 11 and 12A-12C). The one or more word line groups comprises a target word line group (e.g., group 1120 in FIGS. 12A-12C) and one or more other word line groups (e.g., groups 1110 and 1130 in FIGS. 12A-12C) neighboring the target word line group. As shown in FIG. 13, a target word line group comprises a first word line segment (e.g., segment 1123 in FIG. 12C) and a second word line segment (e.g., segment 1124 in FIG. 12C).

The memory device further comprises a memory controller (e.g., local controller 135 shown in FIGS. 1A and 1C) configured to control voltages for memory pillar portions and word line segments in an erase pulse. In some embodiments as shown in FIG. 13, at least one or more of steps are performed within an erase pulse time period. These steps include preparing for electrical isolation of a memory pillar portion associated with the target word line group, electrically isolating a memory pillar portion associated with the target word line group, boosting the voltage of the isolated memory pillar portion, and performing the erase operation. As shown in FIG. 13, an erase pulse comprises an erase pulse ramping up and preparing word line groups period, an electronically isolating period, an erase pulse flattop and voltage booting period, and an erase pulse ramping down period.

During the erase pulse ramping up and preparing word line groups period, for preparing the target word line group and the one or more other word line groups for electrical isolation, the memory controller applies an erase voltage to one or more bit lines and one or more common source (SRC) lines of the target word line group and the one or more other word line groups. As shown in FIG. 13, the erase voltage Vₑᵣₐ is a sufficiently high voltage for erasing data in the memory block. The memory controller further applies a first target word line voltage Vₜ₁ to the word lines of the target word line group. As shown in FIG. 13, the memory controller causes word lines of the first word line segment and the second word line segment at the first target word line voltage Vₜ₁ (section 1301). The first voltage Vₜ₁ is a low voltage. For example, the first target word line voltage Vₜ₁=0 V. As shown in FIG. 13, during the erase pulse ramping up and preparing word line groups period, a voltage of the memory pillar associated with the one or more word groups ramps up toward the erase voltage Vₑᵣₐ (section 1302).

With reference still to FIG. 13, during the electrically isolating period, the voltage of the memory pillar is at the erase voltage Vₑᵣₐ (section 1303). During the erase pulse flattop and voltage booting period, for boosting a voltage of the isolated memory pillar portion associated with the target word line group, the memory controller applies a second target word line voltage Vₜ₂ to word lines of at least one word line segment of the target word line group. In some embodiments as shown in FIG. 13, the second target word line voltage Vₜ₂ is greater than the first target word line voltage Vₜ₁. For example, the second target word line voltage Vₜ₂ is 8 V, while the first target word line voltage Vₜ₁ is 0V. As shown in FIG. 13, the memory controller performs the erase operation of the first word line segment and the second word line segment in different time periods. The memory controller performs the erase operation of the first word line segment, when the second word line segment is used to boost the voltage of the isolated memory pillar portion associated with the target word line group (Section 1304). The memory controller performs the erase operation of the second word line segment, when the first word line segment is used to boost the voltage of the isolated memory pillar portion associated with the target word line group (Section 1305). As shown in FIG. 13 and described above in connection with FIG. 12C, during the erase pulse flattop and voltage booting period, the voltage of the memory pillar is boosted to a voltage higher than the erase voltage Vₑᵣₐ. As a result, the memory controller can perform an erase operation of the target word line group using a voltage (e.g., the second target word line voltage Vₜ₂) that is the same as or less than the erase voltage Vₑᵣₐ. As shown in FIG. 13, the second target word line voltage Vₜ₂ is less than the erase voltage Vₑᵣₐ. FIG. 13 further shows that the memory controller can perform the erase operation for both the first and the second word line segment in the target word line group during the flattop and voltage boosting period (Section 1306). As also shown in FIG. 13, in the erase pulse ramping down period, the memory controller causes the memory pillar to ramp down (Section 1307). While FIG. 13 illustrates the erase operation using two word line segments, it is understood that the same or similar erase operation can be performed with more word line segments. For example, if there are three word line segments, one segment can be used to boost the voltage in a memory pillar portion associated with the target word line group, while the erase operation can be performed for the other one or two segments.

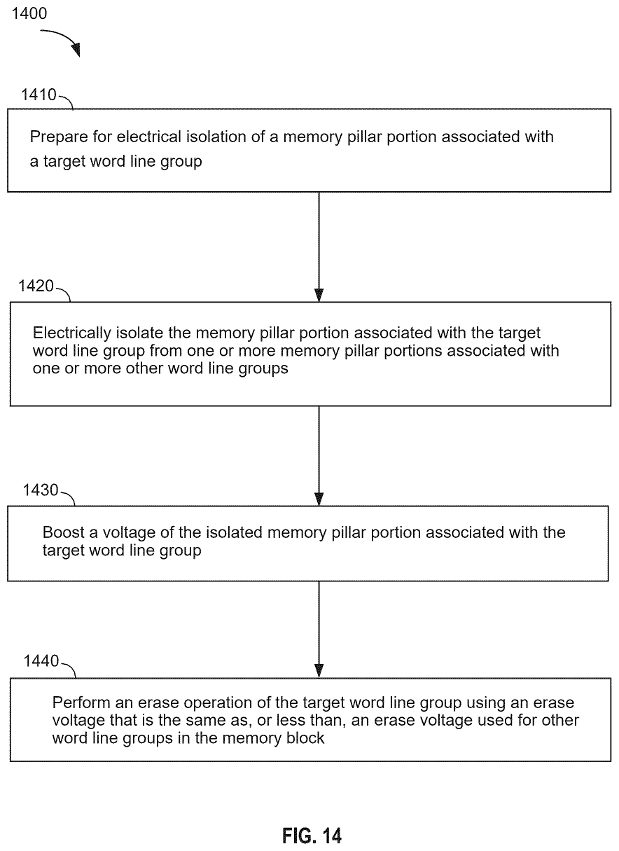

FIG. 14 shows a flowchart 1400 representing an example method for reducing a maximum erase voltage in an erase operation in a memory device according to some embodiments. The memory device (e.g., memory devices 130 shown in FIG. 1A) comprises a plurality of memory blocks (e.g., memory blocks 170 shown in FIG. 1A). Each of the plurality of memory block comprises one or more word line groups. Each of the one or more word line groups comprises a plurality of word line segments including multiple word lines. In some embodiments, the one or more word lines groups of the memory block comprises a top deck, a middle deck, and a bottom deck.

The memory device further comprises a memory controller (e.g., local controller 135 shown in FIGS. 1A and 1C) configured to control voltages in the erase operation. In some embodiment, the one or more word line groups comprise a target word line group and one or more other word line groups neighboring the target word line group. In some embodiments, the target word line group comprises a plurality of word line segments in the top deck, the middle deck, or the bottom deck. In block 1410 of method 1400, the memory controller prepares for electrical isolation of a memory pillar portion associated with the target word line group.

In block 1420 of method 1400, the memory controller electrically isolates the memory pillar portion associated with the target word line group from one or more memory pillar portions associated with one or more other word line groups.

In block 1430 of method 1400, the memory controller boosts a voltage of the isolated memory pillar portion associated with the target word line group.

In block 1440 of method 1400, the memory controller performs an erase operation of the target word line group using an erase voltage that is the same as, or less than, an erase voltage used for the one or more memory pillar portions associated with the one or more other word line groups in the memory block.

In some embodiments, at least one or more of the steps of preparing for electrical isolation of a memory pillar portion associated with the target word line group, electrically isolating the memory pillar portion associated with the target word line group, boosting the voltage of the isolated memory pillar portion, and performing the erase operation are performed within an erase pulse time period.

In some embodiments, method 1400 can include further steps not shown in FIG. 14. For example, prior to preparing for electrical isolation of a memory pillar portion associated with the target word line group, the memory controller receives an erase operation command for erasing data in the memory block. And response to receiving the erase operation command, the memory controller selects the target word line group for boosting the voltage of the isolated memory pillar portion associated with the target word line group.

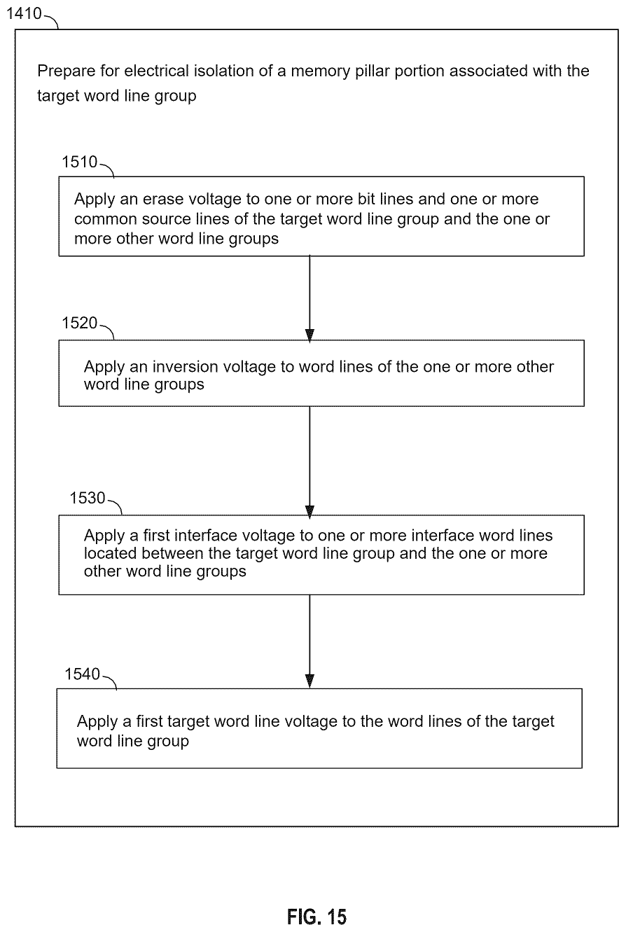

FIG. 15 shows a flowchart illustrating an example method 1410 for preparing for electrical isolation of a memory pillar portion according to some embodiments. The block 1410 in FIG. 15 is the same block 1410 in FIG. 14. The memory controller prepares for electrical isolation of a memory pillar portion associated with the target word line group.

In block 1510 of method 1410, the memory controller applies an erase voltage to one or more bit lines and one or more SRC lines of the target word line group and the one or more other word line groups. The erase voltage is a high voltage for erasing data in the memory block.

In block 1520 of method 1410, the memory controller applies an inversion voltage to word lines of the one or more other word line groups. In some embodiment, the inversion voltage is sufficiently greater than the erase voltage to cause channel inversion in the other word line groups.

In block 1530 of method 1410, the memory controller applies a first interface voltage to one or more interface word lines located between the target word line group and the one or more other word line groups. In some embodiments, the first interface voltage is sufficiently less than the erase voltage to supply holes to the memory pillar portion of the target word line group.

In block 1540 of method 1410, the memory controller applies a first target word line voltage to the word lines of the target word line group.

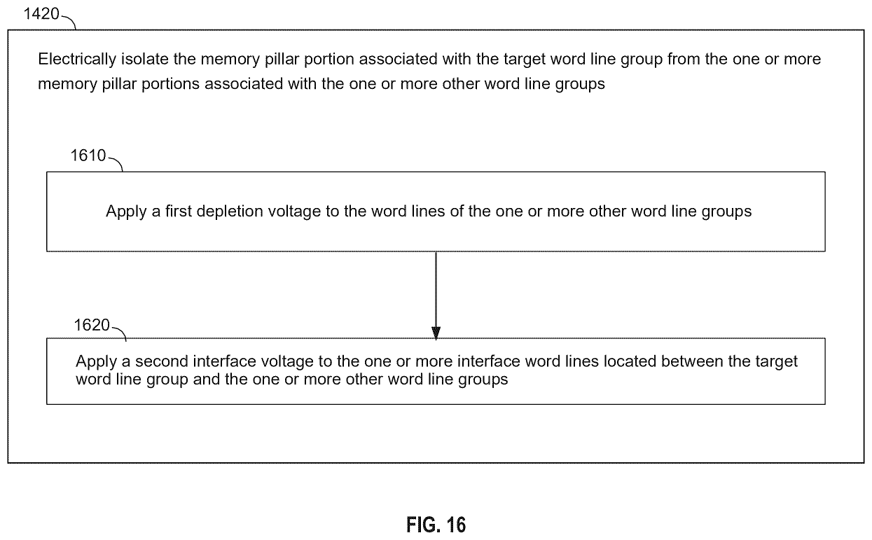

FIG. 16 shows a flowchart illustrating an example method 1420 for electrically isolating a memory pillar portion according to some embodiments. The block 1420 in FIG. 16 is the same block 1420 in FIG. 14. The memory controller electrically isolates a memory pillar portion associated with the target word line group from one or more memory pillar portions associated with the one or more other word line groups. In some embodiments, the isolated memory pillar portion associated with the target word line group forms at least a part of a n-p-n-p structure with one or more of: other memory pillar portions, bit line, SRC line, and interface word lines.

In block 1610 of method 1420, the memory controller applies a depletion voltage to the word lines of the one or more other word line groups. In some embodiments, the depletion voltage is sufficient to cause channel depletion in the other word line groups.

In block 1620 of method 1420, the memory controller applies a second interface voltage to the one or more interface word lines located between the target word line group and the one or more other word line groups. In some embodiments, the second interface voltage is sufficient to cause channel depletion or inversion in the interface word lines.

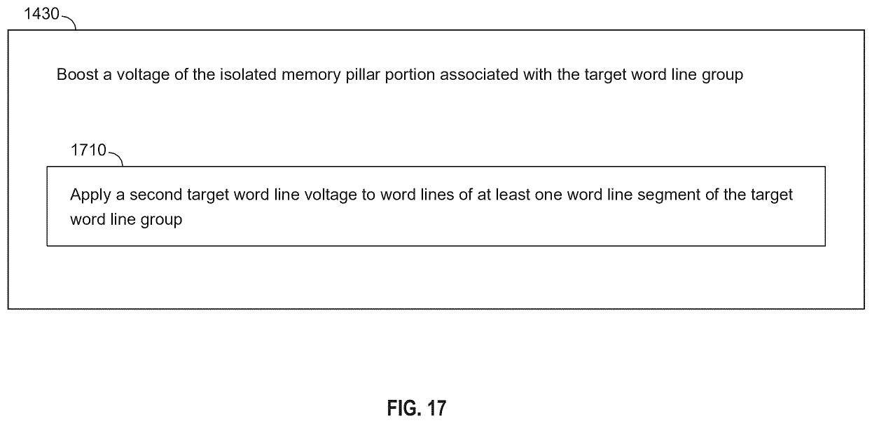

FIG. 17 shows a flowchart illustrating an example method 1430 for boosting a voltage of the isolated memory pillar portion according to some embodiments. The block 1430 in FIG. 17 is the same block 1430 in FIG. 14. The memory controller boosts a voltage of the isolated memory pillar portion associated with the target word line group.

In block 1710 of method 1430, the memory controller applies a second target word line voltage to word lines of at least one word line segment of the target word line group. In some embodiments, the second target word line voltage is greater than the first target word line voltage.

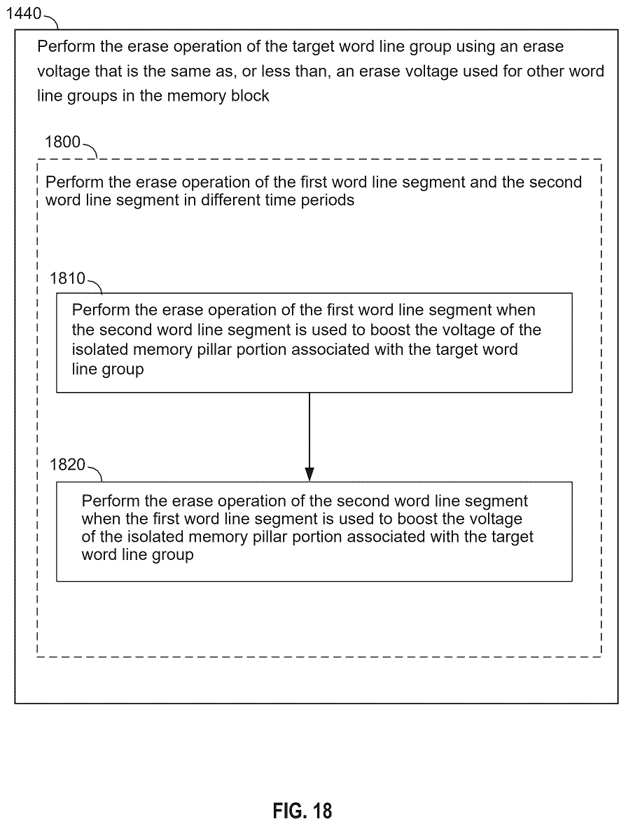

FIG. 18 shows a flowchart illustrating an example method 1440 for performing an erase operation of the target word line group using word line segmentation according to some embodiments. The block 1440 in FIG. 18 is the same block 1440 in FIG. 14. The memory controller performs an erase operation of the target word line group using a voltage that is the same as or less than an erase voltage used for other word line groups in the memory block. The target word line group comprises a first word line segment and a second word line segment. FIG. 18 illustrates an example method 1800 for performing the erase operation of the first word line segment and the second word line segment in different time periods.

In block 1810 of method 1800, the memory controller performs the erase operation of the first word line segment, when the second word line segment is used to boost the voltage of the isolated memory pillar portion associated with the target word line group.

In block 1820 of method 1800, the memory controller performs the erase operation of the second word line segment, when the first word line segment is used to boost the voltage of the isolated memory pillar portion associated with the target word line group.

It should be noted that the described techniques include possible implementations, and that the operations and the blocks may be rearranged, reordered, or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor (e.g., processor 310 of FIG. 3), the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device comprising:
a plurality of memory blocks, wherein each of the plurality of memory blocks comprises a plurality of word line segments, wherein each of the plurality of word line segments comprises one or more word lines forming a subset of word lines in the memory block; and
a memory controller configured to perform:
receiving an erase command for erasing data in the memory block;
in response to receiving the erase command, causing to apply one or more erase pulses to the plurality of word line segments to ramp up word lines of different word line segments of the memory block in different time periods such that while data erasing begins at a first word line segment, data erasing does not begin at another word line segment.

2. The memory device of claim 1, wherein for erasing data in the memory block, the plurality of word line segments is partitioned into two word line segments, four word line segments, or eight word line segments.

3. The memory device of claim 1, wherein causing to apply the one or more erase pulses to the plurality of word line segments to ramp up word lines in different word line segments of the memory block in different time periods comprises:
during a first erase pulse of the one or more erase pulses:
keeping word lines of the first word line segment of the plurality of word line segments at a first voltage below an erase voltage for erasing the data in the memory block;
causing one or more memory pillars or bit lines associated with the plurality of word line segments to ramp up toward the erase voltage; and
causing word lines of a second word line segment to ramp up toward a second voltage higher than the first voltage together with the ramping up of the one or more memory pillars or bit lines associated with the plurality of word line segments.

4. The memory device of claim 3, wherein the memory controller is further configured to perform, during the first erase pulse of the one or more erase pulses:
keeping the one or more memory pillars or bit lines associated with the plurality of word line segments at approximately the erase voltage for at least a threshold time period such that data erasing begins at the first word line segment;
causing the one or more memory pillars or bit lines associated with the plurality of word line segments to ramp down; and
causing the word lines of the second word line segment to ramp down.

5. The memory device of claim 4, wherein the memory controller is further configured to perform, during a second erase pulse of the one or more erase pulses:
keeping the word lines of the second word line segment of the plurality of word line segments at approximately the first voltage;
causing the one or more memory pillars or bit lines associated with the plurality of word line segments to ramp up toward the erase voltage; and
causing word lines of the first word line segment to ramp up toward the second voltage higher than the first voltage together with the ramping up of the one or more memory pillars or bit lines associated with the plurality of word line segments.

6. The memory device of claim 5, wherein the memory controller is further configured to perform:
keeping the one or more memory pillars or bit lines associated with the plurality of word line segments at approximately the erase voltage for at least the threshold time period such that data erasing begins at the second word line segment;
causing the one or more memory pillars or bit lines associated with plurality of word line segments to ramp down; and
causing the word lines of the first word line segment to ramp down.

7. The memory device of claim 1, wherein causing to apply the one or more erase pulses to the plurality of word line segments to ramp up word lines in different word line segments of the memory block in different time periods comprises, during a same erase pulse of the one or more erase pulses:
keeping word lines of the first word line segment of the plurality of word line segments at a first voltage below an erase voltage for erasing the data in the memory block;
causing one or more memory pillars or bit lines associated with the plurality of word line segments to ramp up toward the erase voltage;
causing word lines of a second word line segment to ramp up toward a second voltage higher than the first voltage together with the ramping up of the one or more memory pillars or bit lines associated with the plurality of word line segments;
while keeping the one or more memory pillars or bit lines associated with the plurality of word line segments at approximately the erase voltage such that data erasing begins at the first word line segment, causing the word lines of the second word line segment to ramp down toward a third voltage higher than the first voltage;
causing the word lines of the first word line segment to ramp up toward the third voltage; and
causing the word lines of the second word line segment to continue to ramp down toward approximately the first voltage.

8. The memory device of claim 7, wherein the memory controller is further configured to perform:
keeping the word lines of the second word line segment at approximately the first voltage such that data erasing begins at the second word line segment;
causing the word lines of the first word line segment to ramp down toward approximately the first voltage;
keeping the word lines of the first word line segment at approximately the first voltage such that data erasing begins at the first word line segment; and
causing the one or more memory pillars or bit lines associated with the plurality of word line segments to ramp down.

9. The memory device of claim 8, wherein the memory controller is further configured to, during the same erase pulse of the one or more erase pulses:
keeping the one or more memory pillars or bit lines associated with the plurality of word line segments at approximately the erase voltage for a sufficient time period for data erasing at the first word line segment and at the second word line segment to complete.

10. The memory device of claim 1, wherein the one or more erase pulses comprise multiple erase pulses and wherein causing to apply the multiple erase pulses to the plurality of word line segments to ramp up word lines of different word line segments of the memory block in different time periods comprises:
causing to apply, in a sequential manner, each of the multiple erase pulses to a respective word line segment of the plurality of word line segments, such that in any time period of the different time periods, data erasing occurs at only one word line segments of the plurality of word line segments.

11. The memory device of claim 1, wherein the one or more erase pulses comprise multiple erase pulses and wherein causing to apply the multiple erase pulses to the plurality of word line segments to ramp up word lines of different word line segments of the memory block in different time periods comprises:
causing to apply a first erase pulse to two or more word line segments of the plurality of word line segments, such that data erasing of the two or more word line segments begins in the first erase pulse; and
causing to apply, subsequent to applying the first erase pulse, one or more additional erase pulses to one or more other word line segments of the plurality of word line segments, such that data erasing of the one or more other word line segments begins in respective one or more additional erase pulses.

12. The memory device of claim 1, wherein the one or more erase pulses comprise a single erase pulse and wherein causing to apply the single erase pulses to the plurality of word line segments to ramp up word lines of different word line segments of the memory block in different time periods comprises, during the single erase pulse:
causing memory pillars or bit lines of the plurality of word line segments to ramp up toward an erase voltage for erasing the data in the memory block;
in any time period of the different time periods for ramping up word lines of different word line segments,
keeping word lines of only one of the plurality of word line segments at a first voltage below the erase voltage, and
causing word lines of other word line segments of the plurality of word line segments to ramp up toward a second voltage higher than the first voltage.

13. The memory device of claim 12, wherein a number of the plurality of word line segments is greater than two.

14. A system, comprising:
a processor;
a memory device coupled to the processor, the memory device comprising:
a plurality of memory blocks, wherein each of the plurality of memory blocks comprises a plurality of word line segments, wherein each of the plurality of word line segments comprises one or more word lines forming a subset of word lines in the memory block; and
a memory controller configured to perform:
receiving an erase command for erasing data in the memory block;
in response to receiving the erase command, causing to apply one or more erase pulses to the plurality of word line segments to ramp up word lines of different word line segments of the memory block in different time periods such that while data erasing begins at a first word line segment, data erasing does not begin at another word line segment.

15. A memory device comprising:
a plurality of memory blocks, wherein each of the plurality of memory blocks comprises one or more word line groups, wherein each of the one or more word line groups comprises a plurality of word line segments including multiple word lines;
a memory controller configured to perform:
preparing for electrical isolation of a memory pillar portion associated with a target word line group;
electrically isolating the memory pillar portion associated with the target word line group from one or more memory pillar portions associated with one or more other word line groups;
boosting a voltage of the isolated memory pillar portion associated with the target word line group; and
performing an erase operation of the target word line group using a voltage that is the same as, or less than, an erase voltage used for other word line groups in the memory block.

16. The memory device of claim 15, wherein one or more word lines groups of the memory block comprises a top deck, a middle deck, and a bottom deck.

17. The memory device of claim 16, wherein the target word line group comprises a plurality of word line segments in the top deck, the middle deck, or the bottom deck.

18. The memory device of claim 15, wherein preparing for electrical isolation of a memory pillar portion associated with the target word line group comprises:
applying an erase voltage to one or more bit lines and one or more common source (SRC) lines of the target word line group and the one or more other word line groups;
applying an inversion voltage to word lines of the one or more other word line groups;
applying a first interface voltage to one or more interface word lines located between the target word line group and the one or more other word line groups; and
applying a first target word line voltage to the word lines of the target word line group.

19. The memory device of claim 18, wherein:
the inversion voltage is sufficiently greater than the erase voltage to cause channel inversion in the one or more other word line groups; and
the first interface voltage is sufficiently less than the erase voltage to supply holes to the memory pillar portion of the target word line group.

20. The memory device of claim 18, wherein electrically isolating the memory pillar portion associated with the target word line group from the one or more memory pillar portions associated with the one or more other word line groups comprises:
applying a depletion voltage to the word lines of the one or more other word line groups; and
applying a second interface voltage to the one or more interface word lines located between the target word line group and the one or more other word line groups.

21. The memory device of claim 20, wherein:
the depletion voltage is sufficient to cause channel depletion in the one or more other word line groups; and
the second interface voltage is sufficient to cause channel depletion or inversion in the one or more interface word lines.

22. The memory device of claim 20, wherein boosting the voltage of the isolated memory pillar portion associated with the target word line group comprises:
applying a second target word line voltage to word lines of at least one word line segment of the target word line group.

23. The memory device of claim 22, wherein the second target word line voltage is greater than the first target word line voltage.

24. The memory device of claim 15, wherein the memory controller is further configured to, prior to preparing for electrical isolation of a memory pillar portion associated with the target word line group:
receiving an erase operation command for erasing data in the memory block; and
in response to receiving the erase operation command, selecting the target word line group for boosting the voltage of the isolated memory pillar portion associated with the target word line group.

25. The memory device of claim 15, wherein the target word line group comprises a first word line segment and a second word line segment, and wherein performing the erase operation to the target word line group comprises:
performing the erase operation of the first word line segment and the second word line segment in different time periods.

26. The memory device of claim 25, wherein performing erase operation of the first word line segment and the second word line segment in different time periods comprises:
performing the erase operation of the first word line segment when the second word line segment is used to boost the voltage of the isolated memory pillar portion associated with the target word line group; and
performing the erase operation of the second word line segment when the first word line segment is used to boost the voltage of the isolated memory pillar portion associated with the target word line group.

27. The memory device of claim 15, wherein at least one or more of the steps of preparing for electrical isolation of a memory pillar portion associated with the target word line group, electrically isolating the memory pillar portion associated with the target word line group, boosting the voltage of the isolated memory pillar portion, and performing the erase operation are performed within an erase pulse time period.

28. The memory device of claim 15, wherein the isolated memory pillar portion associated with the target word line group forms at least a part of a n-p-n-p structure with one or more of: other memory pillar portions, bit line, SRC line, and interface word lines.

29. A system, comprising:
a processor;
a memory device of coupled to the processor, the memory device comprising:
a plurality of memory blocks, wherein each of the plurality of memory blocks comprises one or more word line groups, wherein each of the one or more word line groups comprises a plurality of word line segments including multiple word lines;
a memory controller configured to perform:
preparing for electrical isolation of a memory pillar portion associated with a target word line group;
electrically isolating the memory pillar portion associated with the target word line group from one or more memory pillar portions associated with one or more other word line groups;
boosting a voltage of the isolated memory pillar portion associated with the target word line group; and
performing an erase operation of the target word line group using a voltage that is the same as, or less than, an erase voltage used for other word line groups in the memory block.
